(19) United States
(12) Patent Application Publication
(10) Pub. No.: US 2022/0346278 A1
(43) Pub. Date: Oct. 27, 2022

(54) COOLING DEVICE

(71) Applicant: FUJITSU LIMITED, Kawasaki-shi (JP)

(72) Inventors: Masahide KODAMA, Kawasaki (JP); Hideo Kubo, Kawasaki (JP); KENJI SASABE, Kawasaki (JP); Nobumitsu Aoki, Kawasaki (JP); ATSUSHI ENDO, Kawasaki (JP); Keita Hirai, Kawasaki (JP)

(73) Assignee: FUJITSU LIMITED, Kawasaki-shi (JP)

(21) Appl. No.: 17/583,253

(22) Filed: Jan. 25, 2022

(30) Foreign Application Priority Data
Apr. 23, 2021 (JP) 2021-073279

(51) Int. Cl. H05K 7/20; F28F 13/08

(52) U.S. Cl. CPC H05K 7/20336; F28F 13/08; H05K 7/20309; H05K 7/20318; H05K 7/20409; H05K 7/20327; F28F 2215/08

(57) ABSTRACT

A cooling device includes: a container in which a refrigerant is sealed; an evaporation circuit that evaporates the refrigerant in a liquid phase inside the container by heat reception; a condensation circuit that condenses the refrigerant in a gas phase inside the container by heat radiation; a transport circuit that transports the refrigerant in the liquid phase inside the container to the evaporation circuit by a capillary phenomenon; a heat radiation member that includes fins, and includes a narrow portion that has a width in a direction orthogonal to a flow direction of cooling air that is narrow on a downstream side in the flow direction, and a wide portion that has the width that is wide on an upstream side in the flow direction; and an air guide member that is provided on the downstream side of the wide portion and on the upstream side of the narrow portion.

### CROSS-REFERENCE TO RELATED APPLICATION

This application is based upon and claims the benefit of priority of the prior Japanese Patent Application No. 2021-73279, filed on Apr. 23, 2021, the entire contents of which are incorporated herein by reference.

### FIELD

The embodiments discussed herein are related to a cooling device.

### BACKGROUND

There is a cooling device in which an evaporative cooling unit includes a heat radiation unit, a connection unit, and an evaporation unit, and a refrigerant is sealed inside.

Japanese Laid-open Patent Publication No. 2018-133529 is disclosed as related art.

### SUMMARY

According to an aspect of the embodiments, a cooling device includes: a container in which a refrigerant is sealed; an evaporation circuit that evaporates the refrigerant in a liquid phase inside the container by heat reception; a condensation circuit that condenses the refrigerant in a gas phase inside the container by heat radiation; a transport circuit that transports the refrigerant in the liquid phase inside the container to the evaporation circuit by a capillary phenomenon; a heat radiation member that includes a plurality of fins attached to an outside of the container, and includes a narrow portion that has a width in a direction orthogonal to a flow direction of cooling air that is relatively narrow on a downstream side in the flow direction, and a wide portion that has the width that is relatively wide on an upstream side in the flow direction; and an air guide member that is provided on the downstream side of the wide portion but on the upstream side of the narrow portion, and guides the cooling air that has passed through the wide portion to the narrow portion.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view illustrating a cooling device according to a first embodiment;

FIG. 2 is an exploded perspective view illustrating the cooling device of the first embodiment;

FIG. 3 is a partial plan view illustrating an electronic device including the cooling device of the first embodiment together with an internal structure of the cooling device;

FIG. 4 is a plan view illustrating the internal structure of the cooling device of the first embodiment;

FIG. 5 is a cross-sectional view taken along a line 5-5 of FIG. 4, illustrating the cooling device of the first embodiment in a non-inclined state;

FIG. 6 is a cross-sectional view illustrating the cooling device of the first embodiment in an inclined state;

FIG. 7 is a plan view illustrating one end portions of transport pipes in the cooling device of the first embodiment together with a part of an evaporation unit;

FIG. 8 is a cross-sectional view illustrating another end portion of the transport pipe in the cooling device of the first embodiment together with a part of a container;

FIG. 9 is a side view illustrating the one end portion of the transport pipe in the cooling device of the first embodiment together with a part of the evaporation unit;

FIG. 10 is a graph indicating a relationship between an inner diameter of the transport pipe and a height of a water column rising in the transport pipe;

FIG. 11 is a cross-sectional view illustrating a state where a refrigerant evaporates in the cooling device of the first embodiment;

FIG. 12 is a cross-sectional view illustrating a state where the refrigerant condenses in the cooling device of the first embodiment;

FIG. 13 is a cross-sectional view taken along a line 13-13 of FIG. 4, illustrating the cooling device of the first embodiment;

FIG. 14 is a plan view illustrating an electronic device including the cooling device of the first embodiment;

FIG. 15 is a perspective view illustrating the cooling device according to the first embodiment;

FIG. 16 is a perspective view illustrating the cooling device according to the first embodiment;

FIG. 17 is a plan view illustrating the internal structure of the cooling device of the present disclosure together with an injection hole and an injection pipe;

FIG. 18 is a cross-sectional view taken along a line 18-18 of FIG. 17, illustrating the internal structure of the cooling device of the present disclosure;

FIG. 19 is a cross-sectional view illustrating the injection pipe of the cooling device of the present disclosure in an unsealed state;

FIG. 20 is a cross-sectional view illustrating the injection pipe of the cooling device of the present disclosure in a compressed and sealed state;

FIG. 21 is a cross-sectional view illustrating the injection hole of the cooling device of the present disclosure in a state of being sealed with a plug at a tip of the injection pipe;

FIG. 22 is a perspective view illustrating a cooling device according to a first modification;

FIG. 23 is a perspective view illustrating a cooling device according to a second embodiment;

FIG. 24 is a perspective view illustrating the cooling device according to the second embodiment;

FIG. 25 is a perspective view illustrating the cooling device according to the second embodiment;

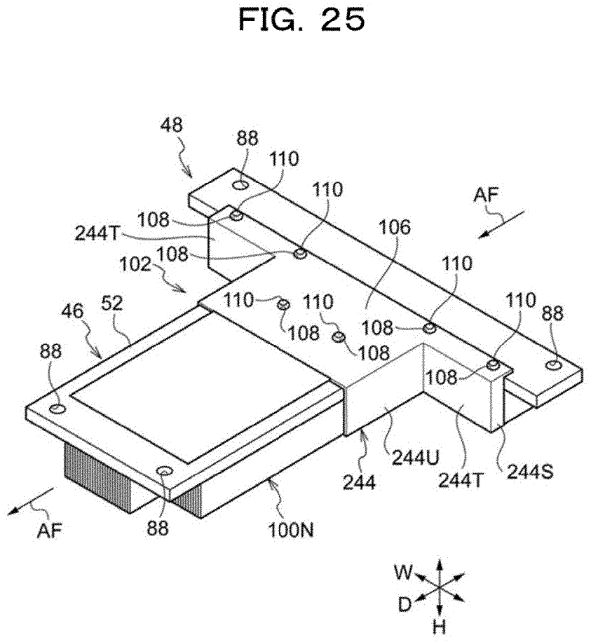

FIG. 26 is a plan view illustrating an electronic device including the cooling device of the second embodiment;

FIG. 27 is a perspective view illustrating a cooling device according to a third embodiment;

FIG. 28 is a perspective view partially illustrating an electronic device including the cooling device of the third embodiment;

FIG. 29 is a plan view illustrating an electronic device including the cooling device of the third embodiment;

FIG. 30 is a perspective view partially illustrating a second modification of the cooling device of the disclosed technology;

FIG. 31 is a cross-sectional view partially illustrating a third modification of the cooling device of the disclosed technology; and

FIG. 32 is a cross-sectional view partially illustrating the third modification of the cooling device of the disclosed technology.

### DESCRIPTION OF EMBODIMENTS

In the cooling device, the refrigerant receives heat from a heating element in the evaporation unit to evaporate and vaporize, and in the heat radiation unit, the inflowing gaseous refrigerant aggregates and liquefies by heat exchange with an external fluid. Moreover, in the cooling device, a heat radiation fin unit and internal fins promote heat radiation from the refrigerant to enhance the cooling efficiency. After passing through the heat radiation fin unit, the air blown from a fan progresses under the connection unit to be applied to a side surface of a cavity portion of the evaporation unit and branches into the left and right to flow so as to pass through side surfaces of the evaporation unit and the region of an auxiliary air cooling fin unit.

In a cooling device that radiates heat of a target to be cooled with a plurality of fins to cool the target to be cooled, for example, the fin arrangement position may be restricted depending on the equipment area of various components on a substrate. An object is to suppress a decrease in cooling efficiency even when the fin arrangement position is restricted in this way.

A cooling device 42 of a first embodiment will be described in detail with reference to the drawings.

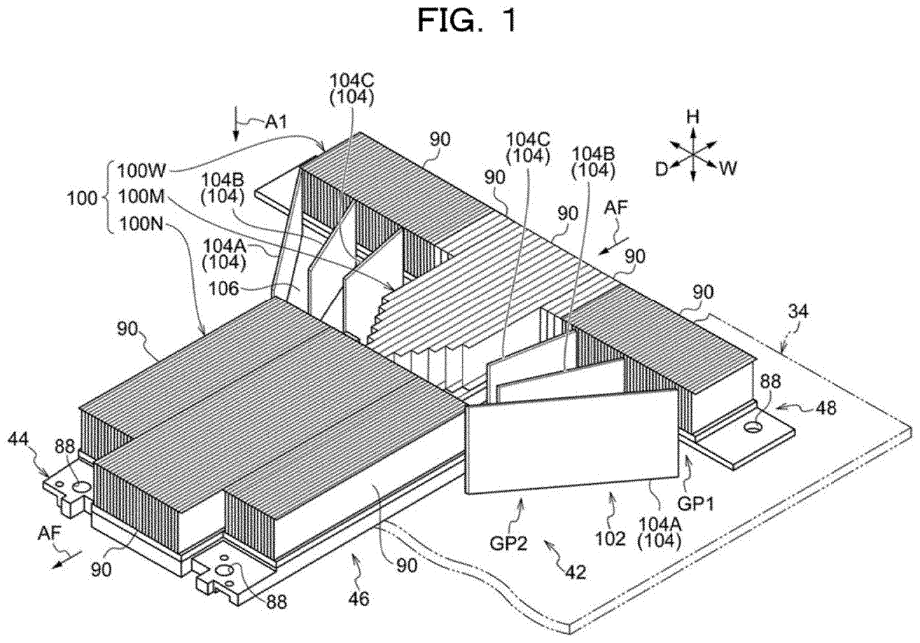

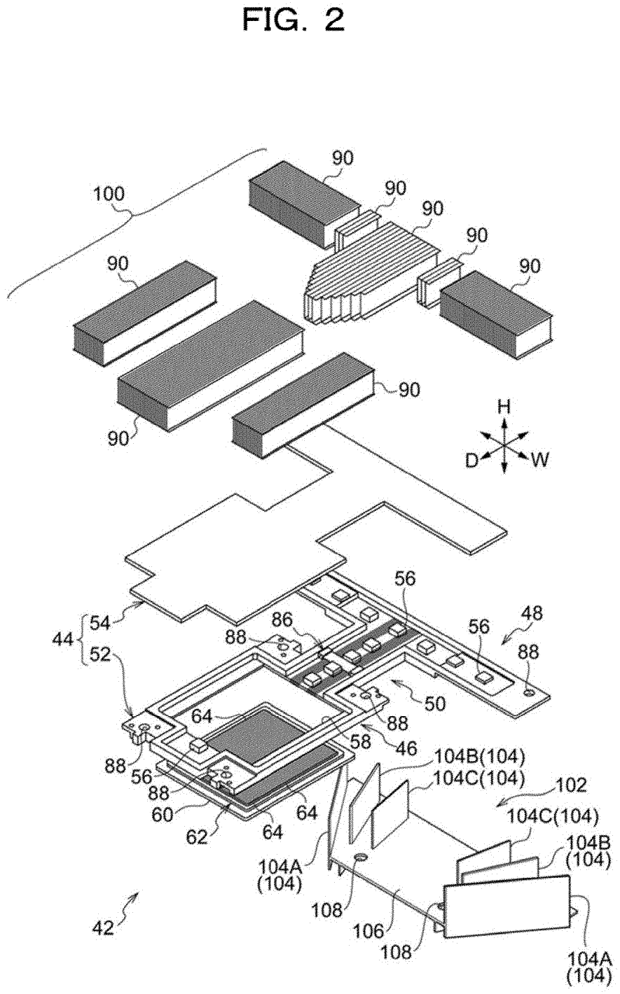

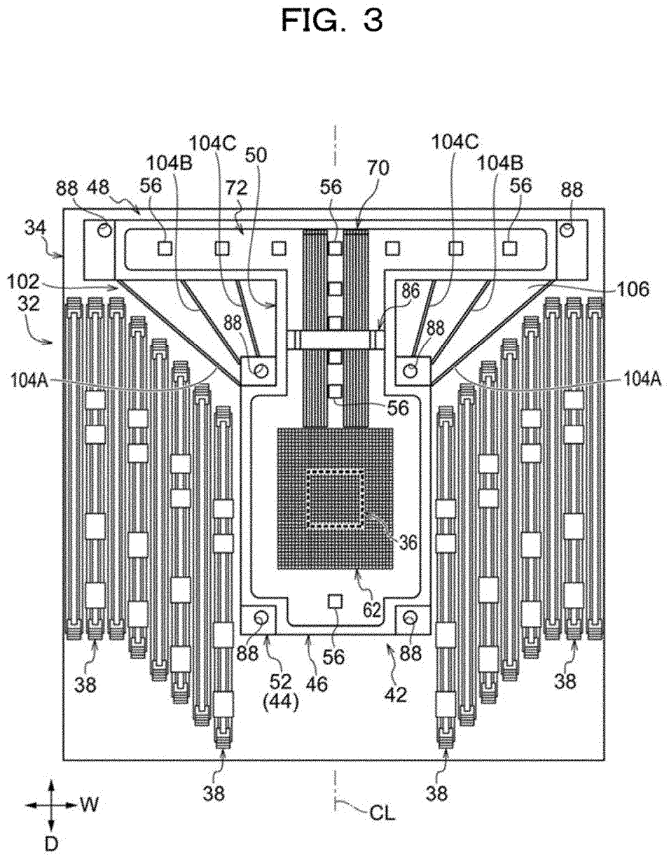

FIGS. 1 and 2 illustrate the cooling device 42 of the first embodiment. Furthermore, FIG. 3 illustrates an electronic device 32 including the cooling device 42. Examples of the electronic device 32 include, but are not limited to, information communication devices such as servers.

The electronic device 32 includes a substrate 34 having rigidity and an insulation property. A plurality of elements 36 and 38 is mounted on the substrate 34. The types of the elements 36 and 38 are not particularly limited, but in the example illustrated in FIG. 3, the element 36 is a processor chip and the elements 38 are memory modules. In this case, the element 36 is an example of a heating element. Then, in order to cool the element 36, the cooling device 42 is arranged in contact with the element 36.

In the drawings, a width direction, a depth direction, and a height direction of the electronic device 32 are indicated by an arrow W, an arrow D, and an arrow H, respectively. In the present embodiment, these width direction, depth direction, and height direction coincide with a width direction, a depth direction, and a height direction of the substrate 34 and a container 44 described later.

As illustrated in FIG. 3, the element 36 is mounted substantially in the center of the substrate 34 with the substrate 34 viewed in plan.

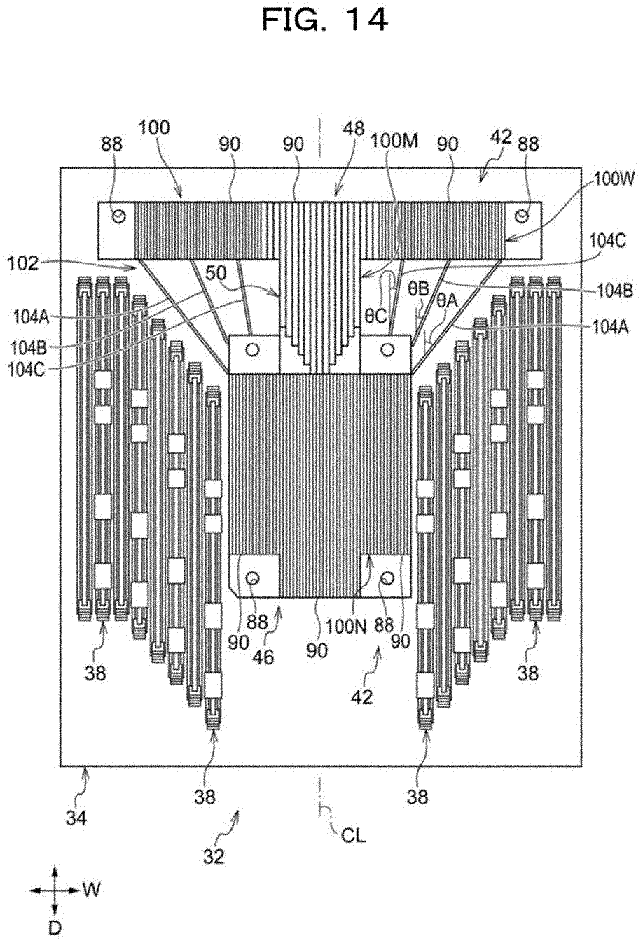

As illustrated in FIGS. 3 and 14, a plurality of the elements 38 is provided and is arranged symmetrically on both sides of the element 36 in the width direction with a center line CL as a center in an orientation in which a longitudinal direction coincides with the depth direction. For example, in the present embodiment, the plurality of the elements 38 is mounted in a stepwise shifting manner so as to be located farther from a heat radiation unit 48 (details will be described later) as approaching the center line CL from both sides in the width direction.

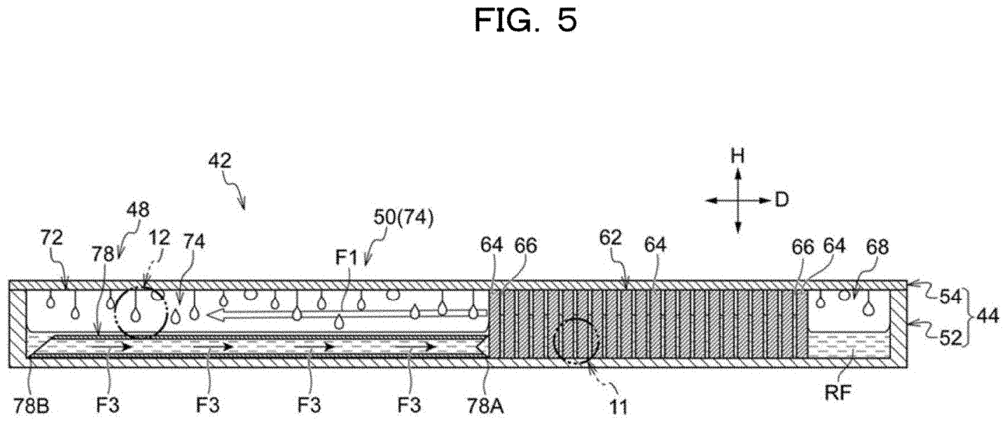

As illustrated in FIGS. 1 to 5, the cooling device 42 includes the container 44. A refrigerant RF (refer to FIG. 5) is sealed inside the container 44. Then, the cooling device 42 includes a heat reception unit 46, the heat radiation unit 48, and a connection unit 50. In the first embodiment, the container 44 is an example of a heat transfer member.

The type of the refrigerant RF is not limited as long as heat is allowed to move by circulating the refrigerant RF while performing a phase transition between a liquid phase and a gas phase in the container 44, and for example, water may be used. Although oil or alcohol may be used instead of water, water is easily available and easy to handle, and water is used also in the present embodiment.

The heat reception unit 46 is a portion that is arranged in contact with the element 36 as illustrated in FIG. 3 and receives heat of the element 36. The heat reception unit 46 includes an evaporation unit 62 that vaporizes the refrigerant RF in the liquid phase by the heat.

The heat radiation unit 48 is a portion that is arranged separately from the heat reception unit 46 and releases heat of the refrigerant RF sealed in the container 44 to the outside. The heat radiation unit 48 includes a condensation unit 72 that liquefies the refrigerant RF in the gas phase by heat radiation.

The connection unit 50 is a portion connecting the heat reception unit 46 and the heat radiation unit 48. Then, the connection unit 50 is also a movement region 74 in which the refrigerant RF moves between the evaporation unit 62 and the condensation unit 72. Note that a part of heat of the refrigerant RF in the gas phase state is discharged to the outside also at the connection unit 50, and the refrigerant RF is liquefied.

In the present embodiment, the heat radiation unit 48 has a shape wider in the width direction and shorter in the depth direction than the heat reception unit 46. The connection unit 50 is narrower in the width direction than the heat reception unit 46 and has a depth for connecting the heat reception unit 46 and the heat radiation unit 48.

In the present embodiment, when the container 44 is viewed in a thickness direction, the heat reception unit 46, the heat radiation unit 48, and the connection unit 50 have a symmetrical shape with the center line CL as a center. Then, the element 36 is in contact with the container 44 on the center line CL at the heat reception unit 46. With this configuration, a temperature distribution of the container 44 that has received heat of the element 36 becomes a distribution close to symmetry with the center line CL as a center.

As illustrated in FIG. 2, the container 44 has a structure in which two plate materials, a bottom plate 52 and a top plate 54, are fixed in a state of being stacked in the thickness direction (height direction).

A plurality of columns 56 is erected from the bottom plate 52. Tips (upper ends) of the columns 56 are in contact with the top plate 54, and the top plate 54 is supported by the columns 56. The inside of the container 44 is maintained in a low pressure state, and even in the low pressure state, the columns 56 maintain an interval between the top plate 54 and the bottom plate 52 and secure an internal volume of the container 44.

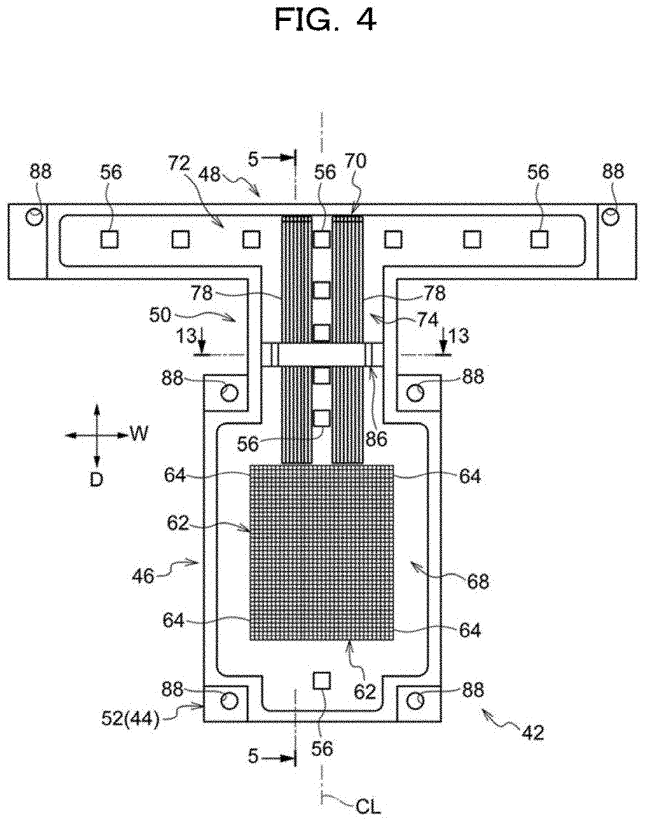

In the present embodiment, as illustrated in FIGS. 2 and 4, a plurality of the columns 56 is arranged in the heat radiation unit 48 at intervals in the width direction of the container 44, and a plurality of the columns 56 is further arranged in the connection unit 50 at intervals in the depth direction of the container 44. Then, also in the heat reception unit 46, one column 56 is provided on an opposite side of the connection unit 50 with the evaporation unit 62 in between.

As illustrated in FIG. 2, in the bottom plate 52, an opening 58 is formed in a portion for the heat reception unit 46. By fitting a heat reception plate 60 into the opening 58, a sealed structure in the container 44 is achieved by the bottom plate 52, the top plate 54, and the heat reception plate 60.

On the heat reception plate 60, a plurality of column members 64 is erected toward the top plate 54. As illustrated in detail also in FIGS. 5 to 7, the plurality of column members 64 is arranged at regular intervals in the width direction and the depth direction, and grid-like grooves 66 are formed between the column members 64. A groove width W1 of the groove 66 is narrower than an inner diameter N1 of a transport pipe 78 described later.

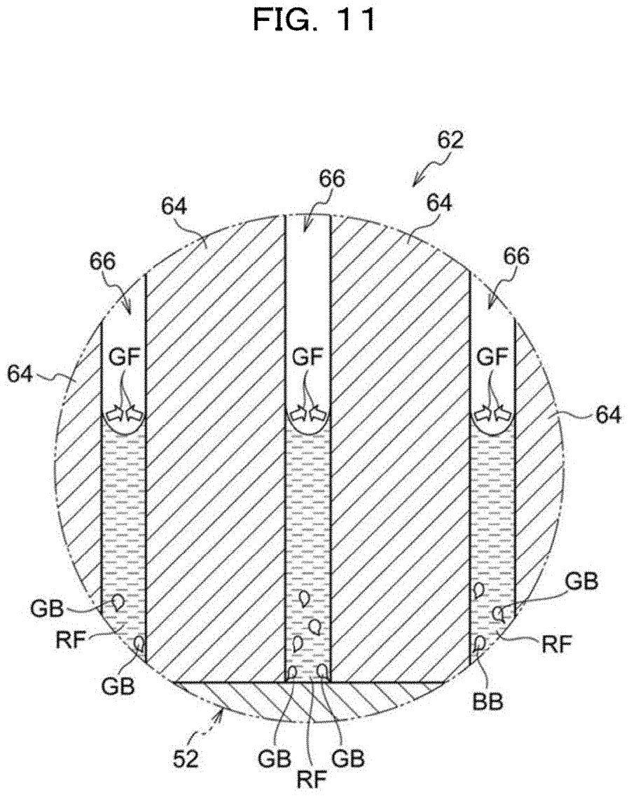

As illustrated in FIG. 11, in the groove 66, vaporization of the refrigerant RF in the liquid phase is promoted by heat from the heat reception unit 46 (refer to FIGS. 1 to 4). This “vaporization” includes, Then to “evaporation” indicating vaporization from a surface of the refrigerant RF as indicated by arrows GF, “boiling” indicating vaporization from the inside of the refrigerant RF as indicated by bubbles GB. Hereinafter, “evaporation” will be used to refer to both of these. A portion including the column members 64 is a portion where the refrigerant RF in the liquid phase evaporates in this way and is the evaporation unit 62.

Tips of the column members 64 are in contact with the top plate 54. Also with this configuration, under the low pressure state inside the container 44, the interval between the top plate 54 and the bottom plate 52 is maintained, and the internal volume of the container 44 is secured.

As illustrated in FIG. 4, around the column members 64, a diffusion region 68 is formed between the top plate 54 and the bottom plate 52. The refrigerant RF in the gas phase evaporated in the evaporation unit 62 diffuses into the diffusion region 68.

Moreover, the movement region 74 is formed between the heat reception unit 46 and the heat radiation unit 48, between the top plate 54 and the bottom plate 52. The refrigerant RF in the gas phase evaporated in the evaporation unit 62 moves to the heat radiation unit 48 through the movement region 74. During this movement, heat of the refrigerant RF is discharged to the outside of the container 44, so that the refrigerant RF in the gas phase is condensed and liquefied. For example, the connection unit 50 and the heat radiation unit 48 are also portions where the refrigerant RF in the gas phase is condensed in this way.

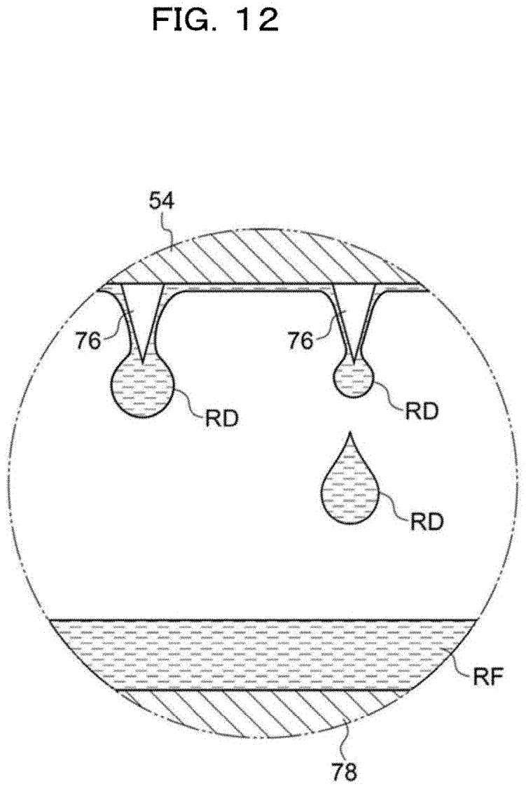

As illustrated in FIG. 12, a plurality of protrusions 76 is formed on the top plate 54 toward the bottom plate 52 (refer to FIG. 5). Each of the protrusions 76 has a shape tapering toward a tip end side. By providing such protrusions 76, as compared with a structure without the protrusions 76, a surface area of a top surface in the condensation unit 72 is large.

As illustrated in FIGS. 4 to 6, a transport unit 70 is arranged between the evaporation unit 62 and the condensation unit 72 inside the container 44. For example, the evaporation unit 62 and the transport unit 70 are arranged in one set corresponding to the condensation unit 72.

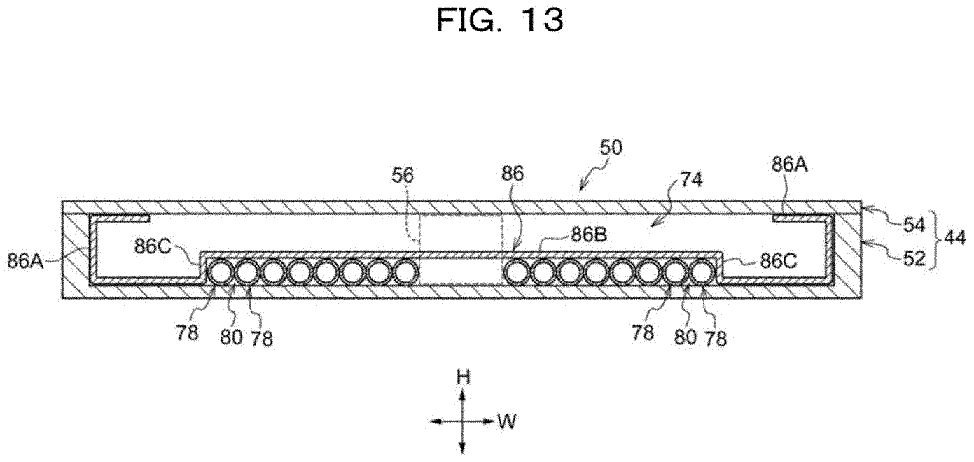

The transport unit 70 has the transport pipes 78 extending in the depth direction. In the transport unit 70, one transport pipe 78 may be arranged, but in the present embodiment, a plurality of transport pipes 78 is arranged in the transport unit 70, and a plurality of transport units 70 is provided. For example, in an example illustrated in FIG. 13, in the transport unit 70, a set of eight transport pipes 78 arranged adjacent to each other in the width direction is arranged in two sets with the column 56 in between, and a total of 16 transport pipes 78 are arranged. The longitudinal direction of the transport pipe 78 coincides with the depth direction of the container 44 (arrow D direction).

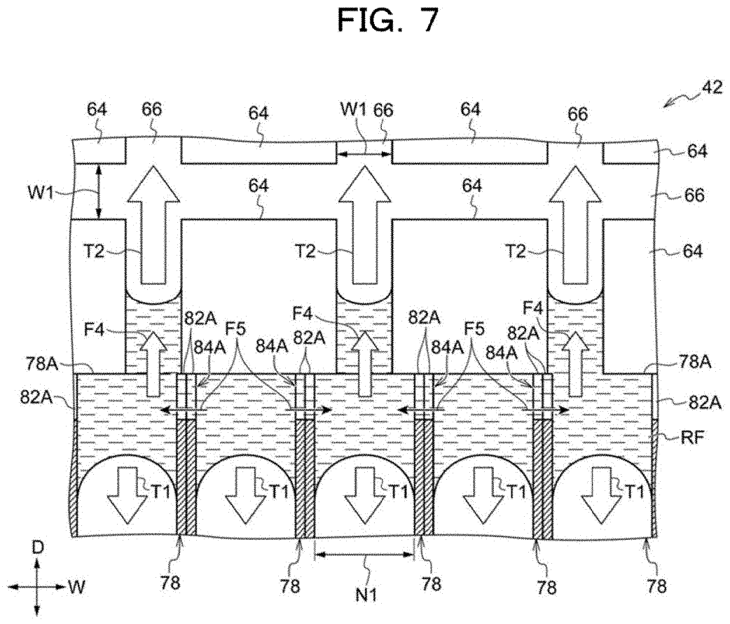

As illustrated in FIG. 7, the inner diameter N1 of the transport pipe 78 is set such that the refrigerant RF in the liquid phase is allowed to be transported by a capillary phenomenon and a sufficient amount of the refrigerant RF is allowed to be transported to the evaporation unit 62 by the whole of the plurality of transport pipes 78.

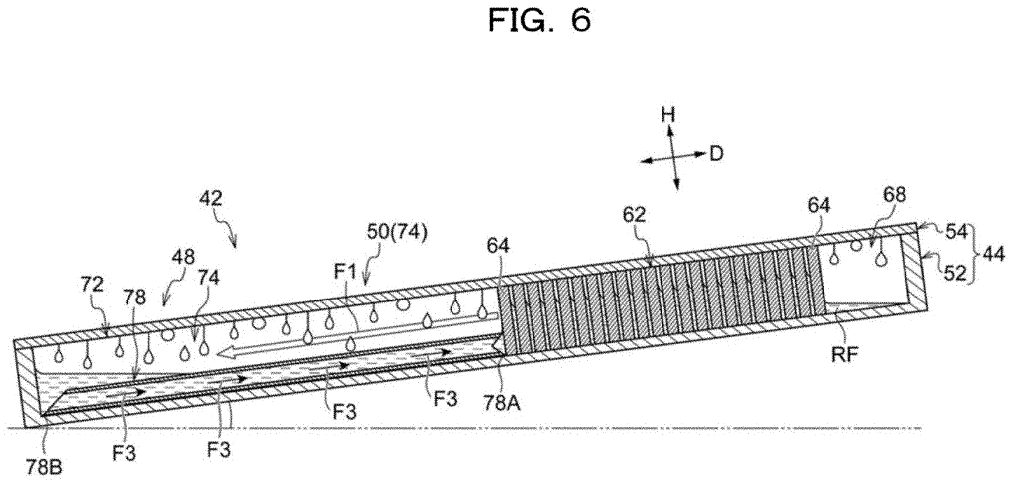

Moreover, an upper limit of the inner diameter N1 of the transport pipe 78 is determined so that the refrigerant RF is allowed to be transported to one end portion 78A from another end portion 78B by the capillary phenomenon even in a case where the cooling device 42 is inclined such that the one end portion 78A is higher than the another end portion 78B (refer to FIG. 6). For example, the inner diameter N1 of the transport pipe 78 is set to the inner diameter N1 that allows a flow rate to be secured within a range where the capillary phenomenon occurs in this way, and the inner diameter N1 of the transport pipe 78 is wider than the groove width W1 of the groove 66 of the evaporation unit 62.

Note that, in the present embodiment, as illustrated in FIG. 13, spaces 80 between the transport pipes 78 arranged adjacent to each other in the width direction and the bottom plate 52 are also regions capable of transporting the refrigerant RF in the liquid phase by the capillary phenomenon.

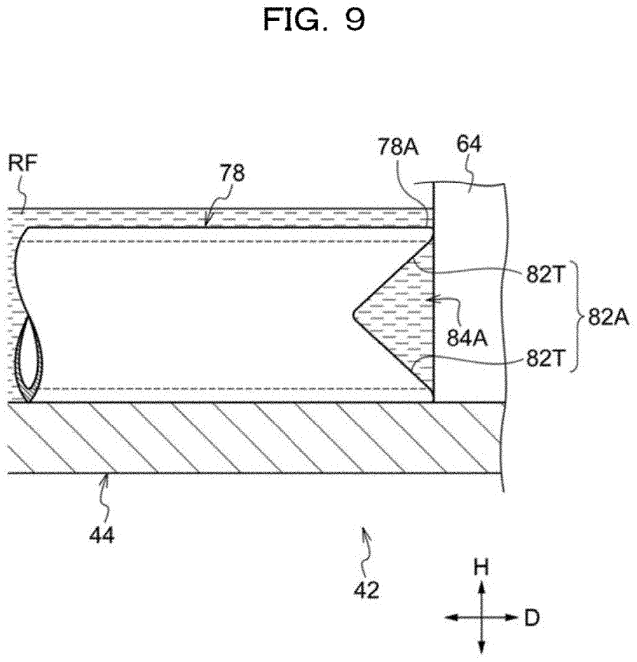

The one end portions 78A of the transport pipes 78 face the column members 64, as also illustrated in FIGS. 7 and 9. In the first embodiment, a gap portion is provided at the one end portion 78A. For example, by cutting out the transport pipe 78 at the one end portion, an inclined portion 82A is formed so as to be inclined relative to the longitudinal direction of the transport pipe 78. The inclined portion 82A is an example of the gap portion in the first embodiment.

For example, in the present embodiment, as illustrated in FIG. 9, the inclined portion 82A has a V-shape having a pair of inclined surfaces 82T formed so as to approach each other as they are separated from the column members 64.

A portion where the inclined portion 82A is provided, which is a region between the inclined surfaces 82T, is a gap 84A in which the refrigerant RF in the liquid phase moves from the transport pipe 78 to the evaporation unit 62.

A plurality of the inclined portions 82A is formed in one transport pipe 78 at regular intervals in a circumferential direction. In the present embodiment, as illustrated in FIG. 7, two inclined portions 82A are formed in one transport pipe 78 so as to be separated from each other in the width direction of the container 44 (arrow W direction).

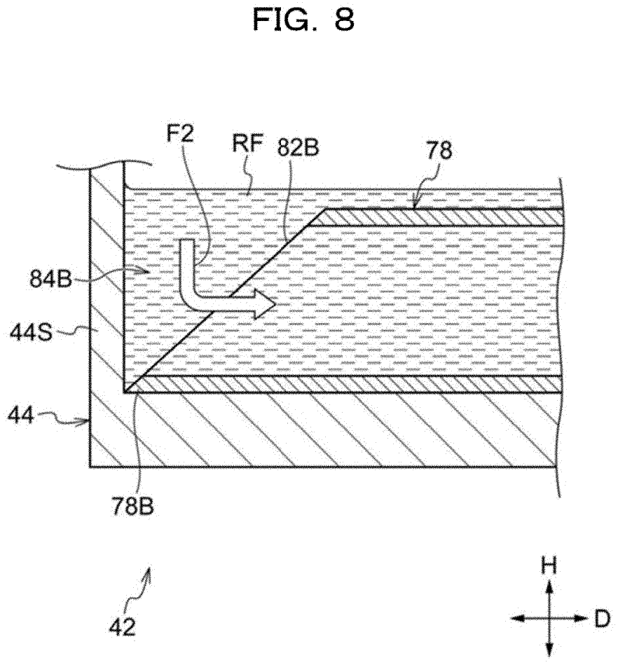

The another end portion 78B of the transport pipe 78 faces a side wall 44S of the container 44, as illustrated in FIG. 8. The side wall 44S is a side wall forming an end on a front side in the depth direction (condensation unit 72 side).

A second gap portion is provided in the another end portion 78B of the transport pipe 78. For example, a second inclined portion 82B is formed by inclining the another end portion 78B in one direction relative to the longitudinal direction of the transport pipe 78, and a region between the side wall 44S and the second inclined portion 82B is a second gap 84B in which the refrigerant RF in the liquid phase moves from the condensation unit 72 into the transport pipe 78.

As also illustrated in FIG. 13, a fixture 86 is arranged inside the container 44 at a portion of the connection unit 50. The fixture 86 includes fitting portions 86A fitted between the top plate 54 and the bottom plate 52 on both sides in the width direction (arrow W direction), and a pressing portion 86B that presses the plurality of transport pipes 78 toward the bottom plate 52 at the center in the width direction. The transport pipes 78 are pressed and fixed to the bottom plate 52 by the pressing portion 86B. Since the plurality of transport pipes 78 is fixed in contact with the bottom plate 52, a sufficient flow path cross-sectional area for the refrigerant RF in the gas phase to substantially move is secured between the top plate 54 and the transport pipes 78.

Moreover, since the sets of the transport pipes 78 are positioned between the column 56 and side surface portions 86C of the pressing portion 86B, the sets are also held in the width direction.

As illustrated in FIGS. 1 to 4, the bottom plate 52 of the container 44 is provided with fastening holes 88. Fasteners such as screws are inserted into the fastening holes 88 and fastened to the substrate 34 to fix the cooling device 42 to the substrate 34. Since the element 36 to be cooled is mounted on the substrate 34, the cooling device 42 is also fixed to the element 36.

With the cooling device 42 fixed to the substrate 34, the element 36 is located between the bottom plate 52 of the container 44 and the substrate 34. Thus, a gap GP1 (refer to FIG. 1) corresponding to the height of the element 36 is formed between the bottom plate 52 and the substrate 34. Since the bottom plate 52 is fixed parallel to the substrate 34, the interval (length) of the gap GP1 is consistent in the width direction and the depth direction.

Note that the top plate 54 has a shape that avoids the fastening holes 88 when viewed in an overlapping direction with the bottom plate 52 (arrow A1 direction illustrated in FIG. 1). Thus, when the cooling device 42 is fixed to the substrate 34, it is possible to perform a fastening operation (for example, a screw turning operation) on the fasteners without being disturbed by the top plate 54.

As illustrated in FIGS. 1 and 2, a heat radiation member 100 is attached to the top plate 54. The heat radiation member 100 includes a plurality of fins 90. These fins 90 are arranged along a flow direction of cooling air from a fan (not illustrated) (arrow AF direction). Each of the plurality of fins 90 has a rectangular plate shape with a flat surface.

The heat of the element 36 (refer to FIG. 3) is transferred to the heat radiation member 100 via the container 44 and radiated from the heat radiation member 100. In the first embodiment, the container 44 is also an example of a heat transfer member that transfers the heat of the element 36 to the heat radiation member 100 in this way.

Then, the fins 90 increase a substantial surface area of the container 44, which is a heat radiation area for heat radiation to the outside (air cooling). For example, in the present embodiment, the fins 90 are installed in substantially an entire area of the top plate 54, and a wide heat radiation area is secured.

As illustrated in FIG. 14, in the heat radiation member 100, a portion arranged at a position corresponding to the heat radiation unit 48 is longer in the width direction than a portion arranged at a position corresponding to the heat reception unit 46 and is a wide portion 100W.

On the other hand, in the heat radiation member 100, the portion arranged at a position corresponding to the heat reception unit 46 is shorter in the width direction than the portion arranged at a position corresponding to the heat radiation unit 48 and is a narrow portion 100N.

Moreover, in the heat radiation member 100, a portion arranged at a position corresponding to the connection unit 50 is still shorter in the width direction than the portion arranged at a position corresponding to the heat reception unit 46 and is a constricted portion 100M.

An air guide member 102 is arranged between the wide portion 100W and the narrow portion 100N, which is a position on a downstream side of the wide portion 100W and on an upstream side of the narrow portion 100N.

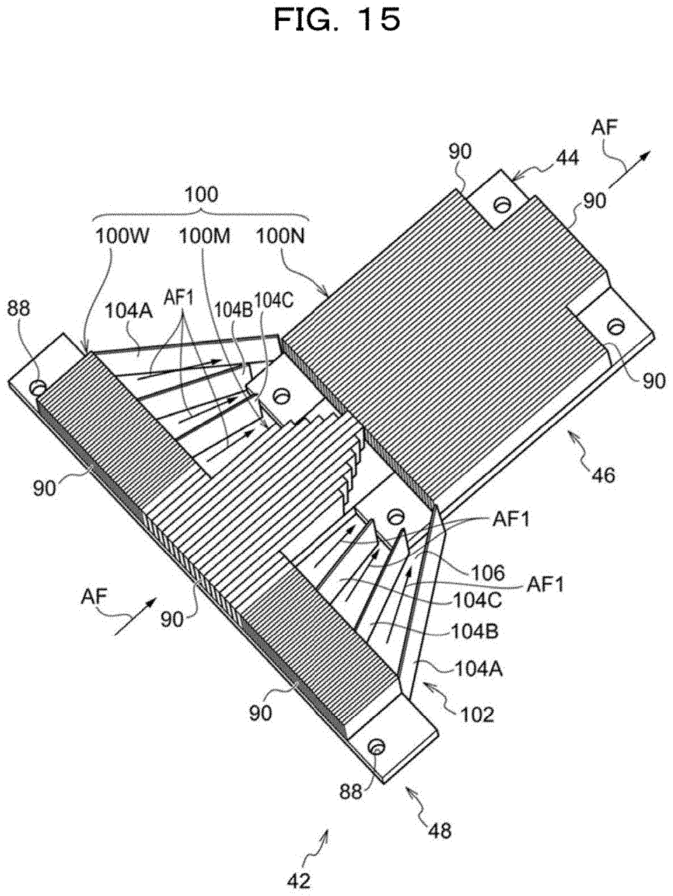

In the first embodiment, as also illustrated in FIG. 15, the air guide member 102 has a plurality of air guide plates 104. One air guide member 102 includes six air guide plates 104 as a whole, which are made up of three air guide plates 104 on each side of the center line CL. In the following, an air guide plate 104A, an air guide plate 104B, and an air guide plate 104C in an order from the outside in the width direction are appropriately distinguished from each other. Each of the air guide plates 104 is a flat plate-shaped member. Then, each of the air guide plates 104 is inclined from the outside to the inside in the width direction from the upstream side toward the downstream side.

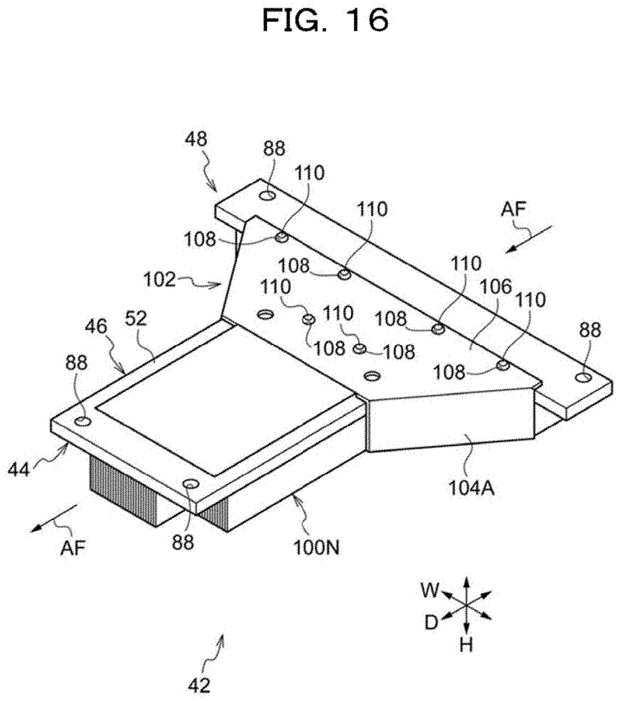

The air guide member 102 further includes an attachment plate 106. As also illustrated in FIG. 16, the attachment plate 106 is an isosceles trapezoidal plate-shaped member that is continuous between the heat reception unit 46 and the heat radiation unit 48. The air guide plate 104A, the air guide plate 104B, and the air guide plate 104C are all joined to the attachment plate 106 and held integrally.

The air guide plate 104A has a shape continuous from an end on the wide portion 100W side (an end on the upstream side) to an end on the narrow portion 100N side (an end on the downstream side) and is arranged in an inclined manner toward the narrow portion 100N relative to the center line CL by a predetermined inclination angle 6A (refer to FIG. 14). The air guide plate 104B is located on an inner side than the air guide plate 104A in the width direction, and an inclination angle 6B of the air guide plate 104B is smaller than the inclination angle 6A of the air guide plate 104A. The air guide plate 104C is located on a further inner side than the air guide plate 104B in the width direction, and an inclination angle 6C of the air guide plate 104C is still smaller than the inclination angle 6B of the air guide plate 104B. Thus, the width of flow of the cooling air that has passed through the wide portion 100W is narrowed down toward the downstream side from the upstream side, and a structure for leading the cooling air toward the narrow portion 100N is achieved.

The attachment plate 106 is fixed to a portion of the bottom plate 52 corresponding to the heat radiation unit 48 on the upstream side and is fixed to a portion of the bottom plate 52 corresponding to the heat reception unit 46 on the downstream side. With this configuration, the attachment plate 106 is fixed to the bottom plate 52 on both of the upstream side and the downstream side. Since the air guide plate 104A, the air guide plate 104B, and the air guide plate 104C are attached to the attachment plate 106, these air guide plates 104 are attached to the container 44 at predetermined positions by fixing the attachment plate 106 to the bottom plate 52.

In a state where the attachment plate 106 is fixed to the bottom plate 52 in this way, a gap GP2 (refer to FIG. 1) is formed between the attachment plate 106 and the substrate 34. On the upstream side of the gap GP2, a portion of the bottom plate 52 corresponding to the heat radiation unit 48 is located in the gap GP1, and the gap GP1 and the gap GP2 are continuous in the flow direction of the cooling air. Then, the elements 38 are located on the downstream side of the gap GP2.

As illustrated in FIGS. 2 and 16, a plurality of screw holes 108 is formed in the attachment plate 106. As illustrated in FIG. 16, the attachment plate 106 may be fixed to the bottom plate 52 by inserting an attachment screw 110 into the screw hole 108 and screwing the attachment screw 110 into a female screw of the bottom plate 52. Note that the structure for fixing the attachment plate 106 to the bottom plate 52 is not limited to such a structure using the screws, and various fixtures such as rivets, pins, and clips may be used. Moreover, brazing, adhesion, or the like may also be used.

In the first embodiment, as illustrated in FIG. 3, the plurality of elements 38 is mounted on the substrate 34 by shifting their positions in a stepwise manner so as to be located on a more downstream side toward the inside from the outside in the width direction. This forms a structure in which the elements 38 and the heat radiation member 100 do not interfere with each other.

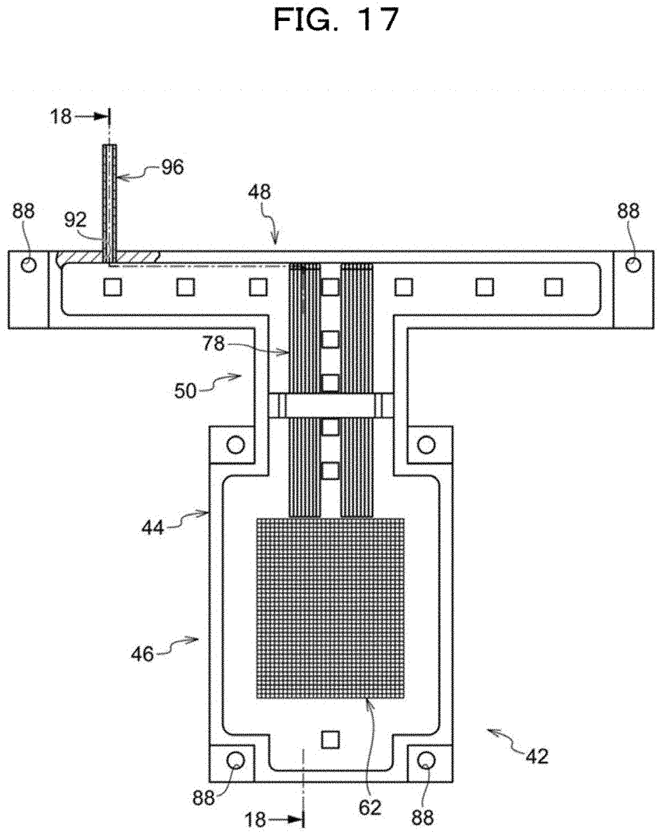

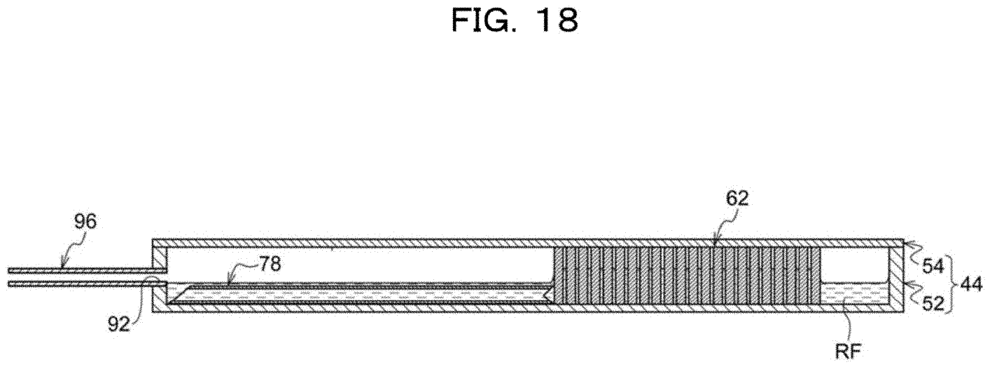

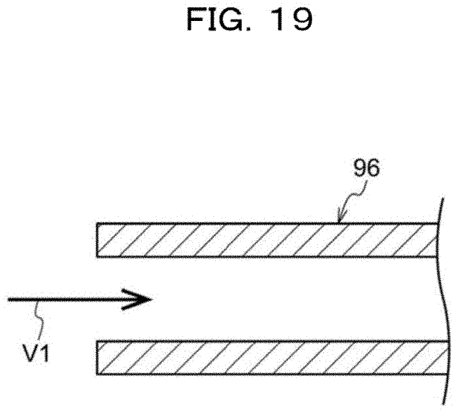

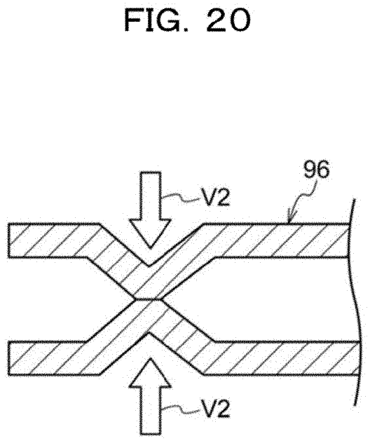

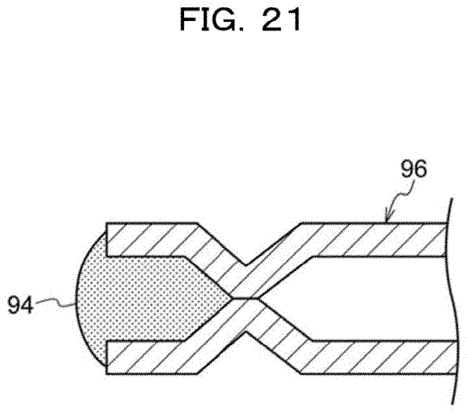

As illustrated in FIGS. 17 and 18, the container 44 is provided with an injection hole 92 that communicates with the inside and the outside of the container 44. An injection pipe 96 extends from the injection hole 92 to the outside of the container 44. To inject the refrigerant RF into the container 44, air in the container 44 is discharged by using a vacuum pump or the like. Thereafter, as indicated by an arrow V1 in FIG. 19, the refrigerant is injected through the injection pipe 96. Then, the refrigerant in the container 44 is heated and boiled, and dissolved air in the refrigerant RF is discharged to the outside of the container 44. Note that this operation is not needed in the case of using a degassed refrigerant from which dissolved air has been removed in advance. Next, as indicated by arrows V2 in FIG. 20, the injection pipe 96 is compressed from the outside and sealed. Moreover, as illustrated in FIG. 21, the injection pipe 96 is more tightly sealed by filling a tip of the injection pipe 96 with a plug 94. For example, since the injection hole 92 is provided, the refrigerant RF may be injected into the inside of the container 44 through the injection hole 92. Then, after the injection, the injection hole 92 is sealed with the plug 94, so that the refrigerant RF may be sealed inside the container 44. Note that, in the drawings other than FIGS. 17 to 21, illustration of the injection hole 92, the plug 94, and the injection pipe 96 are omitted.

Next, actions of the present embodiment will be described.

As illustrated in FIG. 5, when the heat reception unit 46 receives heat from the element 36, the heat vaporizes the refrigerant RF in the liquid phase in the grooves 66 in the evaporation unit 62. For example, as also illustrated in FIG. 11, the refrigerant RF in the liquid phase is put into a gas phase due to evaporation from the surface of the refrigerant RF (refer to the arrows GF) and boiling from the inside of the refrigerant RF (refer to the bubbles GB).

The refrigerant RF in the gas phase is diffused into the diffusion region 68 and moves to the heat radiation unit 48 through the movement region 74 (refer to arrows F1 of FIGS. 5 and 6).

Furthermore, the cooling air from the fan flows in the heat radiation member 100 along the longitudinal direction of the fins 90 (refer to the arrows AF of FIGS. 1 and 15).

In the diffusion region 68 and the movement region 74, a part of the refrigerant RF in the gas phase is condensed and liquefied by heat radiation through the fins 90. Moreover, the refrigerant RF that has reached the heat radiation unit 48 while maintaining the gas phase state is also cooled in the heat radiation unit 48 through the fins 90, so that the refrigerant RF is condensed and liquefied. By liquefying the refrigerant RF in the gas phase in this way, heat of condensation is released from the top plate 54 to the outside of the container 44. As a result, the heat of the element 36 is discharged into the air outside the container 44.

When the heat of the element 36 acts on the container 44, inside the container 44, the refrigerant RF in the liquid phase enters the inside of the transport pipe 78 from the another end portion 78B of the transport pipe 78, as indicated by an arrow F2 in FIG. 8. Moreover, the refrigerant RF is transported to the one end portion 78A, which is, toward the evaporation unit 62, by the capillary phenomenon, as indicated by arrows F3 in FIGS. 5 and 6. Furthermore, also in the spaces 80 between the transport pipes 78 and the bottom plate 52 (refer to FIG. 13), the refrigerant RF in the liquid phase is transported to the evaporation unit 62 by the capillary phenomenon.

Then, in the evaporation unit 62, the refrigerant RF in the liquid phase is evaporated and vaporized again in the grooves 66. In this way, inside the container 44, the refrigerant RF is circulated in the evaporation unit 62 and the condensation unit 72 while repeating the phase transition between the liquid phase and the gas phase. Since the heat received by the heat reception unit 46 may be transferred to the heat radiation unit 48, as described above, the heat may be moved to the wide portion 100W of the heat radiation member 100 provided corresponding to the heat radiation unit 48, and the heat may be radiated from the wide portion 100W.

As illustrated in FIG. 7, in the present embodiment, the groove width W1 of the groove 66 of the evaporation unit 62 is narrower than the inner diameter N1 of the transport pipe 78.

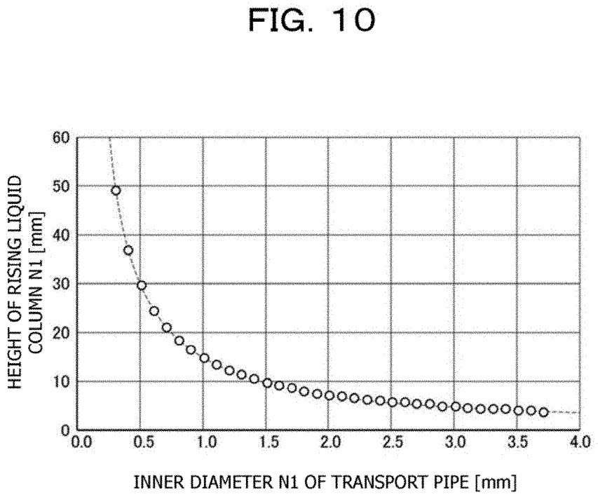

FIG. 10 illustrates a relationship between the inner diameter N1 of the transport pipe 78 and a rising height of a liquid column that rises in the transport pipe 78 due to the surface tension (capillary phenomenon), in a case where a liquid temperature is 25° C. This graph is an example of water used as the refrigerant RF in the present embodiment.

As is seen from this graph, the smaller the inner diameter N1 of the transport pipe 78, the higher the rising height of the liquid column. For example, as the inner diameter N1 is smaller, the refrigerant RF may be raised with larger surface tension.

In the transport pipe 78, as indicated by the arrows F3 in FIGS. 5 and 6, the refrigerant RF in the liquid phase is transported to the evaporation unit 62. However, at the one end portion 78A of the transport pipe 78, as illustrated in FIG. 7, a suction force T1 to the refrigerant RF in a direction away from the evaporation unit 62 may act due to the surface tension of the refrigerant RF in the liquid phase inside. On the other hand, in the evaporation unit 62, a suction force T2 to the refrigerant RF that draws the refrigerant RF into the inside of the evaporation unit 62 may act due to the surface tension of the refrigerant RF in the liquid phase in the grooves 66. The suction force T1 and the suction force T2 are forces in opposite directions, but since the suction force T2 is larger, the refrigerant RF flows from the transport pipe 78 toward the evaporation unit 62 as indicated by arrows F4.

Here, for example, as illustrated in FIG. 6, a case is considered where the cooling device 42 is used in an inclined manner such that the one end portion 78A is higher than the another end portion 78B. As an example, it is assumed that the one end portion 78A is about 25 mm higher than the another end portion 78B. In this case, it may be seen that, when the inner diameter N1 of the transport pipe 78 is set to 0.6 mm or less, the refrigerant RF may be transported from the another end portion 78B toward the one end portion 78A in the transport pipe 78 due to the surface tension.

In this way, from the viewpoint of increasing the surface tension acting on the refrigerant RF in the transport pipe 78, it is sufficient that the inner diameter N1 of the transport pipe 78 is made smaller. Note that, when the inner diameter N1 of the transport pipe 78 is made smaller, the flow path cross-sectional area of the refrigerant RF also becomes smaller, so that the amount of the refrigerant RF that may be transported per unit time also becomes smaller. Thus, a lower limit value of the inner diameter N1 of the transport pipe 78 is determined from the viewpoint of securing the transport amount of the refrigerant RF per unit time.

As illustrated in FIG. 7, in the present embodiment, the groove width W1 of the groove 66 is narrower than the inner diameter N1 of the transport pipe 78. From the relationship illustrated in FIG. 10, the surface tension acting on the refrigerant RF in the liquid phase in the evaporation unit 62 is larger than the surface tension acting on the refrigerant RF in the liquid phase in the transport pipe 78. Thus, by a difference between the suction force T2 and the suction force T1, a force to move from the transport pipe 78 to the evaporation unit 62 may be caused to act, and the refrigerant RF may be moved from the transport pipe 78 to the evaporation unit 62.

Here, a structure in which the one end portion 78A of the transport pipe 78 is formed flat without providing the gap portion is considered. In the transport pipe having the flat one end portion 78A, when an opening portion of the transport pipe faces the column member 64 and an entire circumference of the opening portion is in contact with the column member 64, the opening portion may be covered by the column member 64. By increasing the inner diameter N1 of the transport pipe, it is possible to secure a range that is not covered by the column member 64 at the opening portion of the transport pipe. However, as described above, in order to ensure that the surface tension acts on the refrigerant RF, the inner diameter N1 has an upper limit.

On the other hand, in the present embodiment, the inclined portion 82A is provided at the one end portion 78A of the transport pipe 78 as an example of the gap portion. Then, even when a tip portion of the one end portion 78A is in contact with the evaporation unit 62, the gap 84A is formed between the transport pipe 78 and the evaporation unit 62 so that the one end portion 78A does not contact the evaporation unit 62. For example, the structure is such that the opening portion at the one end portion 78A of the transport pipe 78 is not completely blocked by the column member 64. Thus, as indicated by arrows F5 in FIG. 7, the refrigerant RF in the liquid phase transported by the transport pipe 78 flows into the groove 66 of the evaporation unit 62 through the gap 84A. For example, a structure is achieved that facilitates movement of the refrigerant RF in the liquid phase from the transport pipe 78 to the evaporation unit 62.

In the structure in which the groove width W1 of the groove 66 is narrower than the inner diameter N1 of the transport pipe 78 as described above, the column member 64 becomes relatively thick and covers a wide range of the opening portion of the transport pipe 78. However, even in such a structure, in the present embodiment, since the gap 84A is formed between the transport pipe 78 and the evaporation unit 62, the refrigerant RF in the liquid phase may be reliably moved from the transport pipe 78 to the evaporation unit 62.

In the first embodiment, the gap portion is the inclined portion 82A provided at the one end portion 78A of the transport pipe 78. When the gap portion is provided in the transport pipe 78 in this way, no other member for forming the gap 84A is needed, and the structure of the cooling device 42 may be simplified.

The gap portion is the inclined portion 82A in the example described above. For example, the gap 84A may be formed by the simple structure in which the one end portion 78A of the transport pipe 78 is inclined relative to the longitudinal direction of the transport pipe 78.

As illustrated in FIG. 9, the inclined portion 82A has the pair of inclined surfaces 82T. The inclined surfaces 82T are surfaces that approach each other as they are separated from the evaporation unit 62. By forming the inclined portion 82A including such inclined surfaces 82T, a structure may be achieved in which the gap 84A is formed without making the depth to cut the inclined portion 82A (the length of the portion cut from the evaporation unit 62 side) excessively long.

Note that the one end portion 78A of the transport pipe 78 may also be provided with an inclined portion inclined in one direction in a similar manner to the second inclined portion 82B of the another end portion 78B.

Furthermore, the inclined portion 82A as an example of the gap portion is provided at a plurality of places (two places in the present embodiment) in the circumferential direction in one transport pipe 78. Since a plurality of the gaps 84A is formed by providing the plurality of gap portions, it is possible to secure a cross-sectional area of a portion where the refrigerant RF flows from the transport pipe 78 to the evaporation unit 62 wide, as compared with that of a structure in which only one gap portion is provided in one transport pipe 78.

As illustrated in FIG. 8, the another end portion 78B of the transport pipe 78 is provided with the second inclined portion 82B as an example of the second gap portion, and the second gap 84B is formed between the another end portion 78B and the side wall 44S of the container 44. For example, the structure is such that the opening portion at the another end portion 78B of the transport pipe 78 is not blocked by the side wall 44S. Thus, a structure is achieved in which the refrigerant RF in the liquid phase in the container 44 easily flows into the inside of the transport pipe 78 through the second gap 84B.

In the first embodiment, the transport unit 70 includes the plurality of transport pipes 78. As the transport unit 70, for example, a plate-shaped member or the like having a hole formed as a flow path for the refrigerant RF in the liquid phase may be used instead of or in combination with the transport pipes 78. Since the transport unit 70 has the transport pipes 78, the transport unit 70 may be formed with a simple structure.

Then, the plurality of transport pipes 78 is arranged in parallel. As described above, in terms of increasing the surface tension acting on the refrigerant RF in the liquid phase flowing through the transport pipe 78, since the inner diameter N1 of the transport pipe 78 has an upper limit, it is difficult to secure a sufficient flow rate with only one transport pipe 78. On the other hand, by arranging the plurality of transport pipes 78 in parallel, the transport pipes 78 may secure a larger flow rate as a whole.

The plurality of transport pipes 78 is arranged so that a flow path for the refrigerant RF in the liquid phase is formed also between the two adjacent transport pipes 78 and the bottom plate 52. Since not only the inside of the transport pipe 78 but also the outside of the transport pipe 78 is used as a region where the refrigerant RF in the liquid phase flows, a large flow rate of the refrigerant RF may be secured as compared with a structure in which such a flow path is not formed.

As illustrated in FIG. 4, the condensation unit 72 is formed wider in the width direction (arrow W direction) than the evaporation unit 62. Then, the heat radiation member 100 includes the wide portion 100W on the upstream side thereof. Thus, as compared with a structure in which such a wide portion 100W is not formed, the heat radiation member 100 may secure a wide range to which the cooling air is applied, and condensation of the refrigerant RF may be promoted.

In the first embodiment, in the heat radiation member 100, the narrow portion 100N is present on the downstream side of the wide portion 100W. Then, the air guide member 102 is arranged between the wide portion 100W and the narrow portion 100N. Since the air guide plate 104A, the air guide plate 104B, and the air guide plate 104C of the air guide member 102 are inclined so as to approach the narrow portion 100N from the upstream side toward the downstream side, the cooling air that has passed through the wide portion 100W is guided so as to be narrowed down to the narrow portion 100N. With this configuration, as compared with a structure without the air guide member 102, the cooling air may be effectively collected in the narrow portion 100N, and a large air volume of the cooling air passing through the narrow portion 100N may be secured. Furthermore, since the air guide plate 104A, the air guide plate 104B, and the air guide plate 104C are inclined so as to approach the narrow portion 100N, the cooling air that has passed through the wide portion 100W is applied to the air guide plate 104A, the air guide plate 104B, or the air guide plate 104C, which may suppress the occurrence of turbulent flow.

The narrow portion 100N includes the fins 90 located at positions close to the element 36 to be cooled and has a high contribution to heat radiation. Since the cooling air may be collected and stably supplied to the narrow portion 100N that highly contributes to heat radiation in this way, a high cooling effect on the element 36 may be obtained as the cooling device 42.

For example, in the first embodiment, the wide portion 100W is provided on the upstream side. Even when the shape of the cooling device 42 is restricted by the mounting positions of various mounted components such as the elements 36 and 38 mounted on the substrate 34, the wide portion 100W on the upstream side may secure a wide area for receiving the cooling air. However, when a structure including the wide portion 100W and the narrow portion 100N does not have the air guide member 102, out of the cooling air that has passed through the wide portion 100W, the cooling air that has passed through a position close to an end in the width direction flows to the downstream side without passing through the narrow portion 100N.

On the other hand, in the first embodiment, out of the cooling air that has passed through the wide portion 100W, even the cooling air that has passed through a portion where the fins 90 are not present on the downstream side may be inclusively supplied toward the narrow portion 100N efficiently by the air guide member 102.

In the first embodiment, as exemplified in FIGS. 2, 14, 16 and the like, the air guide member 102 includes the attachment plate 106. The attachment plate 106 may integrally hold the plurality of air guide plates of the air guide plate 104A, the air guide plate 104B, and the air guide plate 104C. Then, by fixing the attachment plate 106 to the bottom plate 52, the plurality of the air guide plates 104 may be attached to the container 44 at predetermined positions. By attaching the plurality of the air guide plates 104 to the container 44 while the air guide plates 104 are held integrally, the plurality of the air guide plates 104 and the container 44 are also integrated, so that the air guide plates 104 may be attached to the container 44 with high accuracy. With this configuration, for example, the generation of inadvertent gaps or the like that will cause turbulent flow of the cooling air may be suppressed.

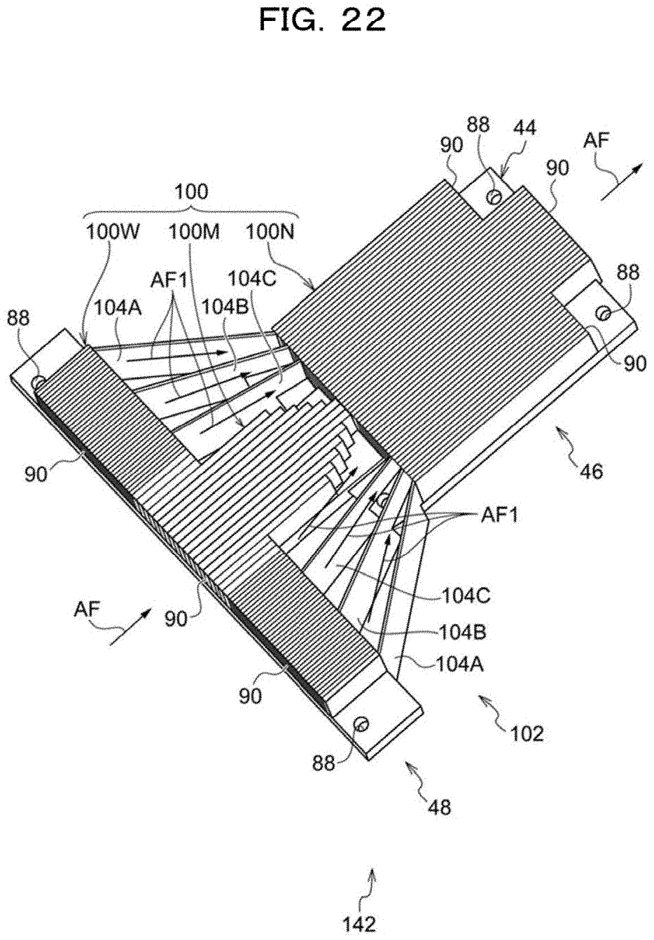

On the other hand, as illustrated in FIG. 22, it is also possible to employ a structure such as the structure of a cooling device 142 of a first modification.

In the cooling device 142 of the first modification, the air guide member 102 does not include the attachment plate 106 (refer to FIG. 16 and the like). Then, the air guide plate 104A, the air guide plate 104B, and the air guide plate 104C are all formed to have a length to reach the heat reception unit 46 from the heat radiation unit 48.

Thus, in the first modification illustrated in FIG. 22, the air guide plate 104A, the air guide plate 104B, and the air guide plate 104C are individually fixed to the heat radiation unit 48 and the heat reception unit 46 on the bottom plate 52.

Note that the cooling air also passes through the gap GP1 between the container 44 and the substrate 34. The elements 38 may be cooled by the cooling air passing through the gap GP1 and being applied to the elements 38. For example, in the first embodiment, since the gap GP2 is formed between the attachment plate 106 and the substrate 34, the elements 38 may be stably cooled by guiding the cooling air to the elements 38 by the gap GP2.

In the first embodiment and the first modification described above, the plurality of the flat plate-shaped air guide plates 104 is provided. Then, the inclination angles (the inclination angles relative to the flow direction of the cooling air) of the plurality of the air guide plates 104 become smaller from the outside in the width direction to the inside in the width direction. With this configuration, the cooling air that has passed through the wide portion 100W may be smoothly narrowed down and supplied to the narrow portion 100N.

Next, a second embodiment will be described. In the second embodiment, elements, members, and the like similar to those in the first embodiment are denoted by the same reference signs as those in the first embodiment, and detailed description thereof will be omitted.

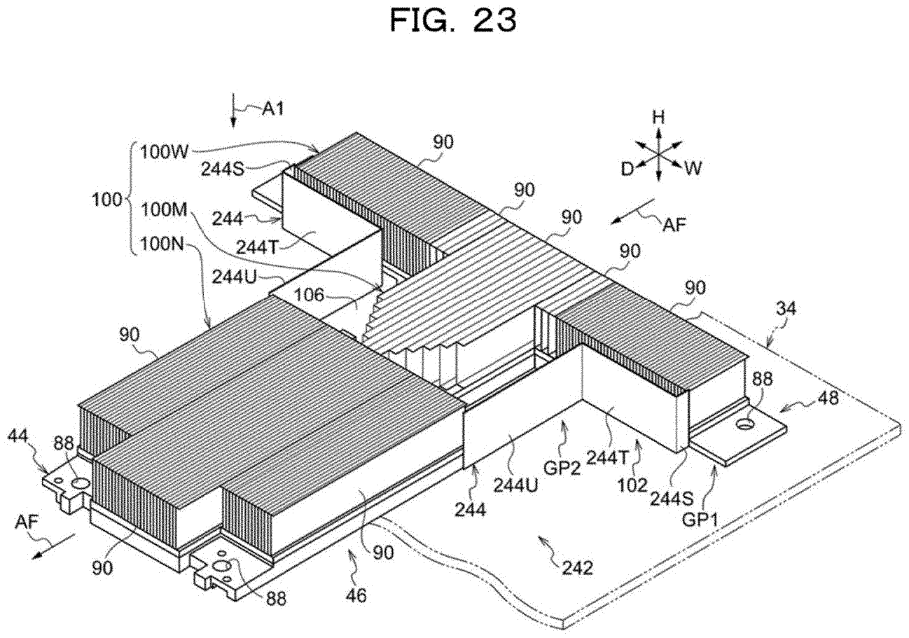

In a cooling device 242 of the second embodiment, as illustrated in FIG. 23, an air guide plate 244 of an air guide member 102 includes an outer plate portion 244S, an inner plate portion 244U, and an intermediate plate portion 244T.

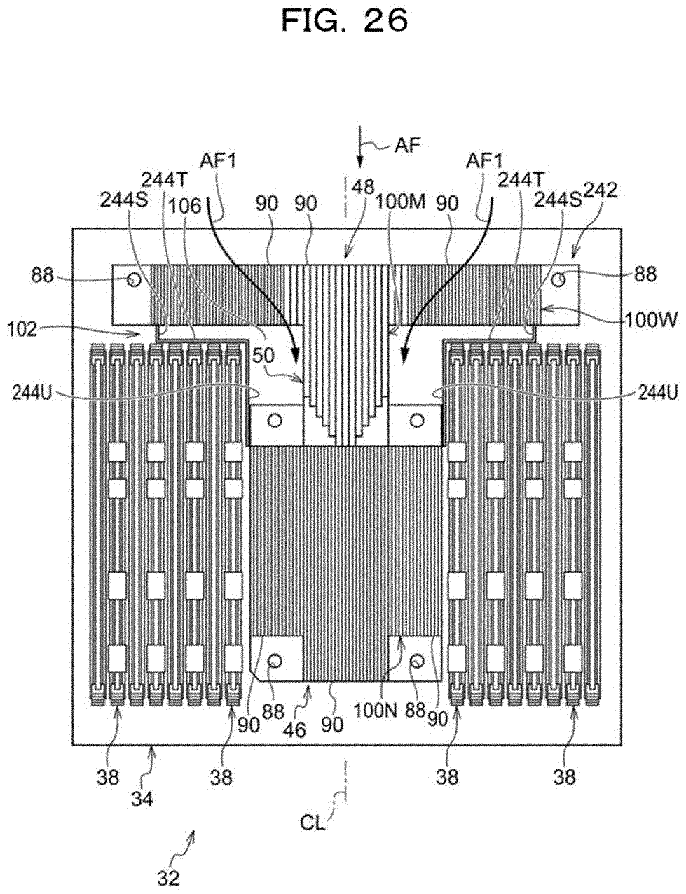

The outer plate portion 244S is a plate-shaped portion extending to the downstream side from a wide portion 100W of a heat radiation member 100. On the other hand, the inner plate portion 244U is a portion extending to the upstream side from a narrow portion 100N of the heat radiation member 100. In the example illustrated in FIG. 23, both of the outer plate portion 244S and the inner plate portion 244U are arranged along the flow direction of the cooling air, which means to be arranged in parallel to the center line CL (refer to FIG. 26).

The intermediate plate portion 244T is continuous with a downstream end of the outer plate portion 244S and an upstream end of the inner plate portion 244U. In the illustrated example, the intermediate plate portion 244T is orthogonal to the flow direction of the cooling air, and a normal direction of the intermediate plate portion 244T coincides with the direction of the center line CL (refer to FIG. 26).

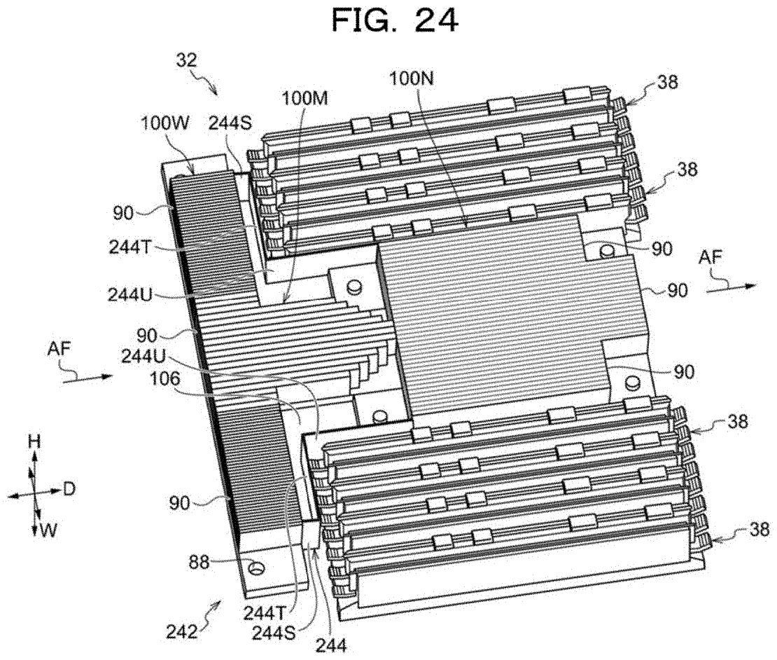

The outer plate portion 244S, the inner plate portion 244U, and the intermediate plate portion 244T are integrally held by being joined to and held by an attachment plate 106. In practice, by bending one plate material at predetermined positions, the air guide plate 244 in which the outer plate portion 244S, the intermediate plate portion 244T, and the inner plate portion 244U are integrated may be formed. Then, the air guide plate 244 in which the three portions are integrated in this way is held by the attachment plate 106. As illustrated in FIG. 24, the air guide plate 244 is attached to a container 44 at a predetermined position by fixing the attachment plate 106 to a bottom plate 52 in the wide portion 100W and the narrow portion 100N.

Also in the cooling device 242 of the second embodiment having such a structure, as indicated by arrows AF1 in FIG. 26, the cooling air that has passed through the wide portion 100W is guided to the narrow portion 100N by the air guide member 102. For example, a part of the cooling air that has passed through the wide portion 100W tends to flow to the outside in the width direction when being applied to the intermediate plate portion 244T of the air guide plate 244 but does not flow out to the outside of the air guide plate 244 in the width direction, because the outer plate portion 244S is located outside in the width direction. Then, the cooling air that has flowed to the inside in the width direction moves to the narrow portion 100N, but here again, the presence of the inner plate portion 244U suppresses the inadvertent leakage of the cooling air to the outside in the width direction. Since the cooling air is guided to the narrow portion 100N in this way, a high cooling effect may be obtained as compared with a structure without the air guide member 102.

In the second embodiment, the intermediate plate portion 244T is orthogonal to the flow direction of the cooling air. Therefore, a plurality of elements 38 may be arranged side by side at the same position without shifting their positions in the flow direction of the cooling air. Then, with this configuration, the upsizing of an electronic device 32 in the depth direction (arrow D direction) may be suppressed.

Also in the second embodiment, the air guide member 102 includes the attachment plate 106. The air guide plate 244 is attached to the container 44 with high accuracy by the attachment plate 106. With this configuration, for example, the generation of inadvertent gaps or the like that will cause turbulent flow of the cooling air may be suppressed.

Note that, in the second embodiment, the intermediate plate portion 244T may also be inclined so as to approach the narrow portion 100N from the upstream side toward the downstream side, similarly to the air guide plate 104 of the first embodiment. In this case, the plurality of elements 38 located on the downstream side of the intermediate plate portion 244T is arranged so as to be sequentially shifted to the downstream side from the outside in the width direction toward the inside in the width direction, as in the example illustrated in FIG. 3, so that a structure in which the elements 38 and the air guide plate 244 do not interfere with each other may be achieved.

Next, a third embodiment will be described. In the third embodiment, elements, members, and the like similar to those in the first embodiment or the second embodiment are denoted by the same reference signs as those in the first embodiment or the second embodiment, and detailed description thereof will be omitted.

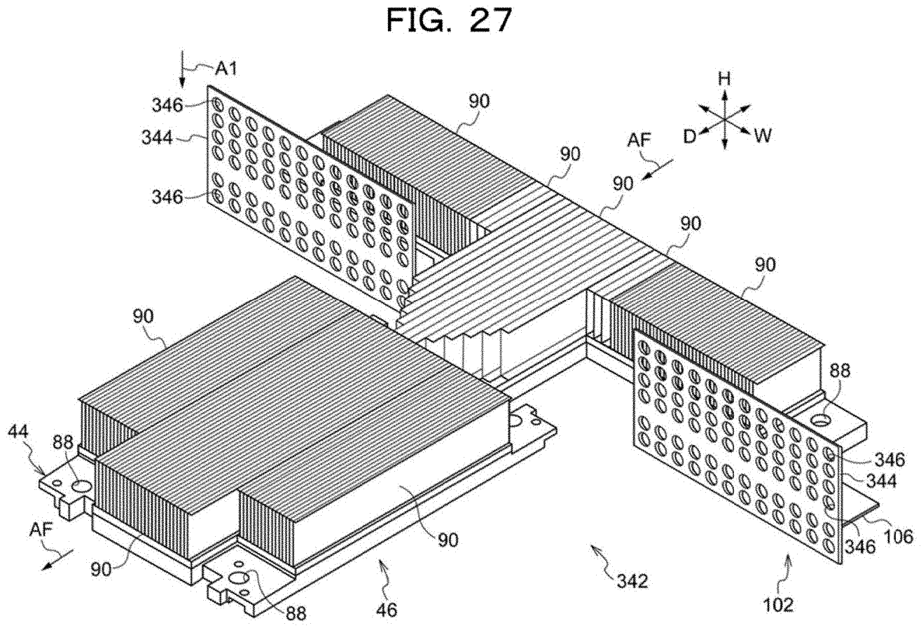

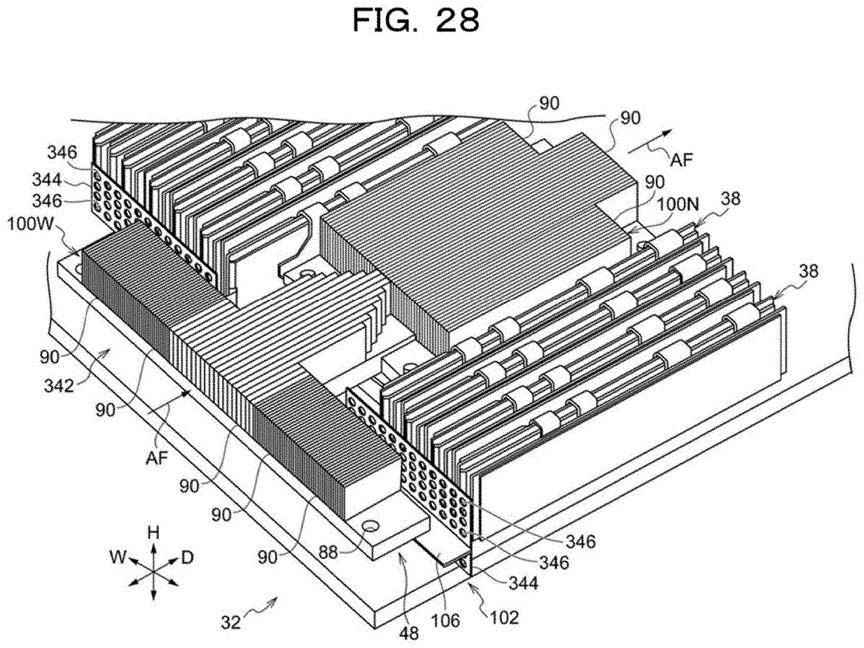

In a cooling device 342 of the third embodiment, as illustrated in FIGS. 27 and 28, an air guide plate 344 of an air guide member 102 is arranged in an orientation orthogonal to the flow direction of the cooling air. Then, a plurality of through holes 346 penetrating in a plate thickness direction is formed in the air guide plate 344. The cooling air is allowed to pass through the through holes 346.

Also in the third embodiment, the air guide plate 344 is held by an attachment plate 106. The air guide plate 344 is attached to a container 44 at a predetermined position by fixing the attachment plate 106 to a bottom plate 52 in a wide portion 100W.

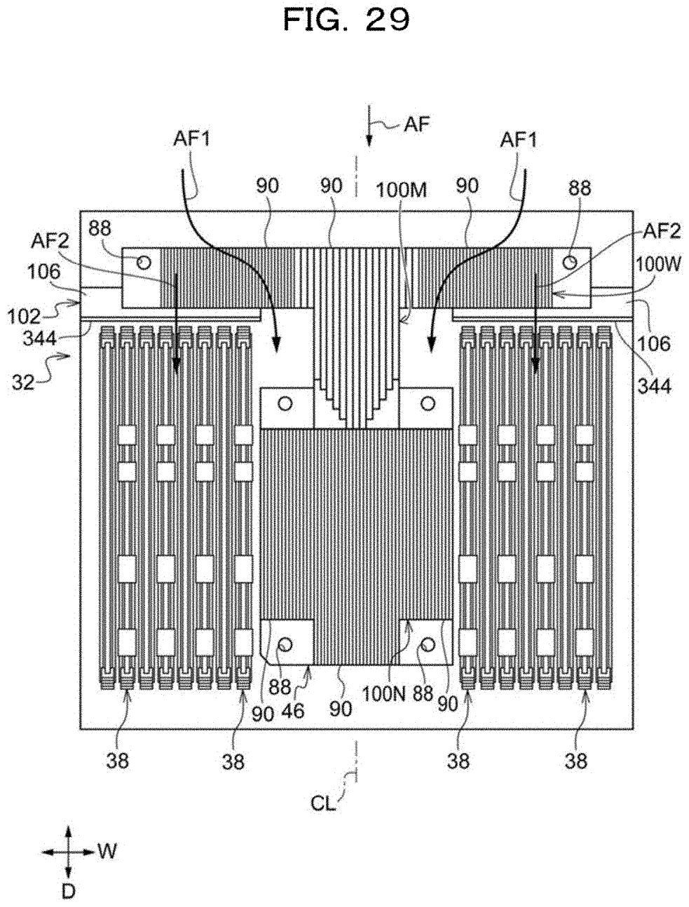

Also in the cooling device 342 of the third embodiment having such a structure, as indicated by arrows AF1 in FIG. 29, the cooling air that has passed through the wide portion 100W is guided to a narrow portion 100N by the air guide member 102, so that a high cooling effect may be obtained as compared with a structure without the air guide member 102.

Furthermore, in the cooling device 342 of the third embodiment, since the through holes 346 are formed in the air guide plate 344, as indicated by arrows AF2 in FIG. 29, a part of the cooling air that has passed through the wide portion 100W progresses through the through holes 346 and flows to the downstream side of the air guide plate 344. Since elements 38 are located on the downstream side of the air guide plate 344, these elements 38 may be cooled by the cooling air that has passed through the through holes 346.

In the third embodiment, the air volume and distribution of the cooling air acting on the elements 38 may be adjusted by adjusting the positions and sizes (opening cross-sectional areas) of the through holes 346.

The shape of the through hole 346 is not limited to a circle and may be a polygon such as a quadrangle or a hexagon. Moreover, by constituting the air guide plate 344 in a mesh structure, a structure in which the plurality of through holes 346 is formed in a grid pattern may also be adopted. Alternatively, by using a porous plate material as the air guide plate 344, pores of the plate material may also act as the through holes 346.

Note that, also in the third embodiment, the air guide plate 344 may be inclined so as to approach the narrow portion 100N from the upstream side toward the downstream side, similarly to the air guide plate 104 of the first embodiment. In this case, if the plurality of elements 38 is arranged so as to be sequentially shifted to the downstream side from the outside in the width direction toward the inside in the width direction, a structure in which the elements 38 and the air guide plate 344 do not interfere with each other may be achieved.

Also in the third embodiment, by fixing the attachment plate 106 to the bottom plate 52, the air guide plate 344 may be attached to the container 44 at a predetermined position. With this configuration, for example, forming of inadvertent gaps or the like that will cause disturbance in the flow of the cooling air between the air guide plate 344 and the container 44 may also be suppressed.

Note that, for example, in the first embodiment, the second embodiment, and the first modification, a through hole similar to the through hole 346 may be formed in the air guide plates 104 and 224. By providing such a through hole, even in the structures of the first embodiment, the second embodiment, and the first modification, a part of the cooling air that has passed through the wide portion 100W may be applied to the elements 38, and the elements 38 may be cooled by the cooling air.

In each of the embodiments and modification described above, the air guide member 102 includes the plate-shaped air guide plates 104, 244, and 344. As the air guide member 102, it is possible to guide the cooling air to the narrow portion 100N with a simple structure in which the plate-shaped members are provided in this way.

In each of the embodiments described above, the air guide member 102 is attached to and integrated with the container 44. With this configuration, the cooling performance may be improved by suppressing forming of inadvertent gaps between the air guide member 102 and the container 44 and stabilizing the flow of the cooling air.

Besides, in each of the embodiments and modification described above, the air guide member 102 is attached to the container 44, so that the state of non-contact with the fins 90 is maintained. Since the air guide member 102 that has received the cooling air does not come into contact with the fins 90, inadvertent deformation of the fins 90 may be suppressed. For example, even if the fin 90 is made thinner in order to further increase the heat radiation area, deformation is suppressed.

Then, when the container 44 is viewed in plan, the air guide member 102 is also present at a visible position. Since the air guide member 102 is integrated with the container 44, the cooling device may be supported using the air guide member 102, for example, at the time of operation such as manufacturing, servicing, or maintenance of the electronic device 32. As described above, since the supportable portions of the cooling devices 42, 242, and 342 are enlarged by the air guide member 102, inadvertent contact with the fins 90 by an operator may be suppressed.

Furthermore, in each of the embodiments and modification described above, the air guide member 102 has a shape bilaterally symmetrical relative to the center line CL of the container. Thus, the cooling air that has passed through the wide portion 100W may be guided to the narrow portion 100N while suppressing a bias between the left and right.

In each of the embodiments and modification described above, the narrow portion 100N of the heat radiation member 100 is arranged in the heat reception unit 46. For example, since a large amount of cooling air may be supplied by the air guide member 102 to the narrow portion 100N that is present at a position close to the element 36 to be cooled, a high cooling effect on the element 36 may be obtained.

In each of the embodiments described above, the structure in which a gap is provided between the transport pipe 78 and the evaporation unit 62 is not limited to that described above.

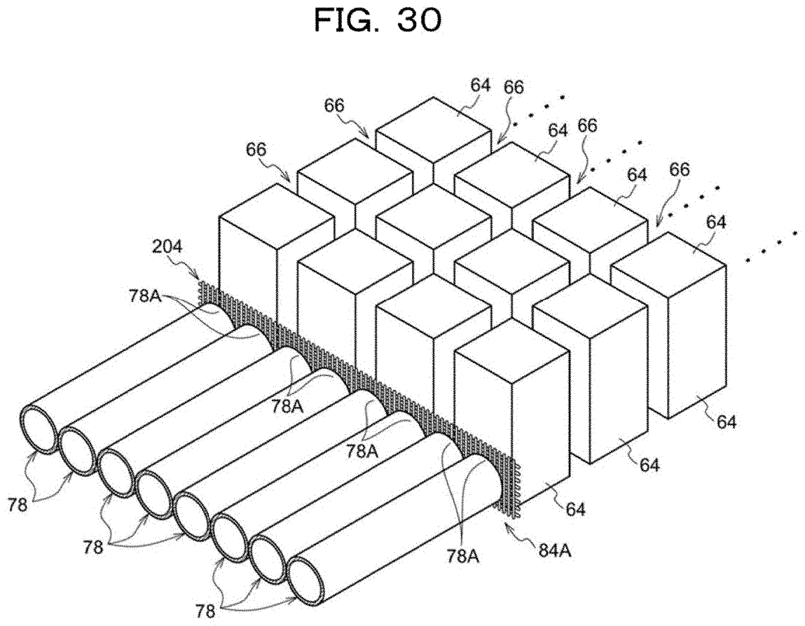

In a second modification illustrated in FIG. 30, as an example of the gap portion, a net member 204 separate from the transport pipe 78 and the evaporation unit 62 is provided. The net member 204 is arranged between the transport pipe 78 and the evaporation unit 62, with one surface in contact with the transport pipe 78 and another surface in contact with the evaporation unit 62. Note that, in the second modification, the inclined portion 82A of the first embodiment (refer to FIG. 9) is not formed at the one end portion 78A of the transport pipe 78, and the one end portion 78A is orthogonal to the longitudinal direction of the transport pipe 78.

The net member 204 is a member that allows fluid to move in the thickness direction (arrow T direction), and the net member 204 forms the gap 84A between the transport pipe 78 and the evaporation unit 62. Thus, the one end portion 78A of the transport pipe 78 is not blocked by the evaporation unit 62, and the flow path for the refrigerant RF from the one end portion 78A toward the evaporation unit 62 is secured. For example, also in the structure illustrated in FIG. 30, the structure is achieved that facilitates movement of the refrigerant RF in the liquid phase from the transport pipe 78 to the evaporation unit 62.

In the second modification illustrated in FIG. 30, the net member 204 as an example of the gap portion is separate from the transport pipe 78 and the evaporation unit 62. Thus, the shape of the transport pipe 78 or the evaporation unit 62 is not affected. For example, the one end portion 78A of the transport pipe 78 does not have to be processed, and the structure may be simplified.

The net member 204 is arranged between the transport pipe 78 and the evaporation unit 62 and is in contact with both of them. With this configuration, a relative position between the transport pipe 78 and the evaporation unit 62 is maintained, so that the state where the gap 84A is formed may also be maintained.

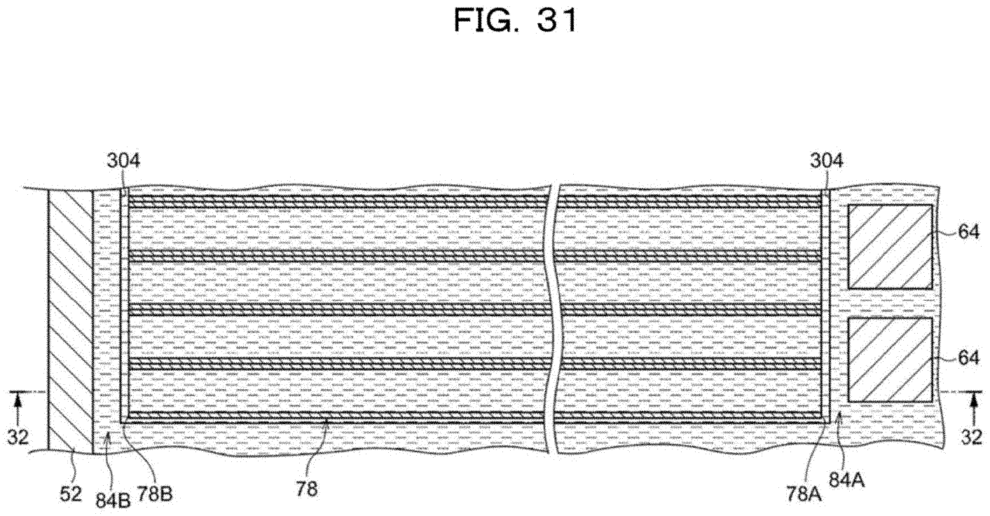

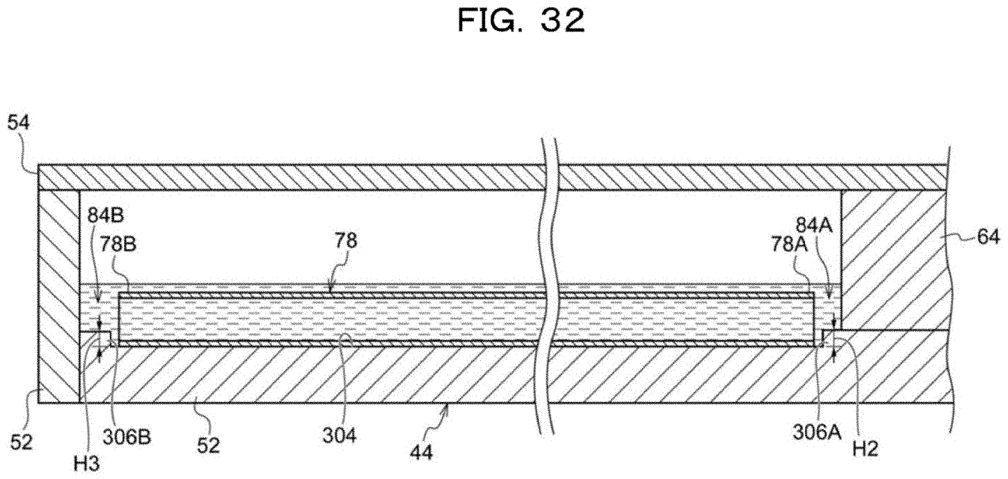

Furthermore, as the structure in which a gap is provided between the transport pipe 78 and the evaporation unit 62, a third modification illustrated in FIGS. 31 and 32 may be applied.

In the third modification, the bottom plate 52 is provided with a recess 304. The recess 304 has a shape capable of accommodating a lower-side portion of each transport pipe 78. Then, as a part of the bottom plate 52, a wall portion 306A is provided between the recess 304 and the evaporation unit 62. Furthermore, as a part of the bottom plate 52, a second wall portion 306B is provided between the recess 304 and the side wall 44S of the container 44. Substantially, the wall portion 306A and the second wall portion 306B are portions of the bottom plate 52 where the recess 304 is not provided.

The wall portion 306A faces the one end portion 78A of the transport pipe 78 and is set to a height H2 that is enough not to obstruct a substantial flow of the refrigerant RF in an inner peripheral portion of the transport pipe 78. Then, the wall portion 306A forms the gap 84A between the one end portion 78A of the transport pipe 78 and the condensation unit 72.

In the third modification, the wall portion 306A forms the gap 84A between the transport pipe 78 and the evaporation unit 62. Thus, the one end portion 78A of the transport pipe 78 is not blocked by the evaporation unit 62, and the flow path for the refrigerant RF from the one end portion 78A toward the evaporation unit 62 is secured. For example, also in the third modification, the structure is achieved that facilitates movement of the refrigerant RF in the liquid phase from the transport pipe 78 to the evaporation unit 62.

The second wall portion 306B faces the another end portion 78B of the transport pipe and is set to a height H3 that is enough not to obstruct the substantial flow of the refrigerant RF in the inner peripheral portion of the transport pipe 78. Then, the second wall portion 306B forms the second gap 84B between the another end portion 78B of the transport pipe 78 and the side wall 44S of the container 44. For example, in the third embodiment, the second wall portion 306B is an example of the second gap portion. Note that, since the height H2 of the wall portion 306A and the height H3 of the second wall portion 306B both correspond to the depth in the recess 304, the height H2 of the wall portion 306A and the height H3 of the second wall portion 306B are equal to each other.

In the third modification, the wall portion 306A as an example of the gap portion is provided in the container 44. Since the gap portion is not provided in the transport pipe 78, the one end portion 78A of the transport pipe 78 does not have to be processed, and the structure may be simplified. Furthermore, since a new member does not have to be provided as the gap portion, the number of components does not increase.

In the third modification, the container 44 is provided with the recess 304. As a portion facing the one end portion 78A of the transport pipe 78, a structure having the gap portion may be achieved with a simple structure.

Furthermore, since the transport pipe 78 is accommodated in the recess 304 of the bottom plate 52, a space between the transport pipe 78 and the top plate 54 may be secured wide as compared with a structure without the recess 304.

In the above, in the evaporation unit 62, the column member 64 is mentioned as a member for forming the groove 66, but the member forming the groove 66 is not limited to the column member. For example, a structure may be adopted in which a plurality of wall members extending in the depth direction is arranged side by side at regular intervals in the width direction. In the structure having the wall members, a groove extending in the depth direction is formed between the wall members.

In each of the embodiments described above, the columns 56 are arranged between the top plate 54 and the bottom plate 52 inside the container 44. Since the interval between the top plate 54 and the bottom plate 52 may be maintained by the columns 56, a volume for circulating the refrigerant RF while making the phase transition between the liquid phase and the gas phase may be secured inside the container 44. For example, the inside of the container 44 is maintained at a low pressure as compared with an atmospheric pressure in order to promote vaporization of the refrigerant RF in the liquid phase. In this case, a force in an approaching direction acts on the top plate 54 and the bottom plate 52 due to the pressure difference between a pressure inside the container 44 (vapor pressure of the refrigerant RF in the gas phase) and the atmospheric pressure. Even when such a force acts, the interval between the top plate 54 and the bottom plate 52 may be maintained.

Note that the columns 56 may also be provided on the top plate 54 and have a structure in which lower ends contact the bottom plate 52, or may also be separate from both of the top plate 54 and the bottom plate 52 and have a structure in which upper ends contact the top plate 54 and the lower ends contact the bottom plate 52.

Since the transport pipes 78 are fixed to the container 44 by the fixture 86, displacement or falling of the transport pipes 78 may be suppressed.

Furthermore, since the transport pipes 78 are not fixed to the container by so-called brazing or adhesion, no solder or adhesive is needed. Since no solder or adhesive is used, the solder or adhesive does not melt due to a temperature change (high temperature) or the like during manufacturing of the cooling device 42.

Furthermore, since the plurality of transport pipes 78 is fixed in contact with the bottom plate 52 by the fixture 86, a sufficient flow path cross-sectional area for the refrigerant RF in the gas phase to substantially move may be secured between the top plate 54 and the transport pipes 78.

The top plate 54 is provided with the protrusions 76. The refrigerant RF in the gas phase that flows while contacting the top plate 54 is condensed and liquefied by heat radiation to the outside of the container 44 through the top plate 54. At this time, as illustrated in FIG. 12, the protrusions 76 increase a substantial contact area in which the refrigerant RF contacts the top plate 54 as compared with a structure without the protrusions 76. With this configuration, the refrigerant RF in the gas phase is easily liquefied as droplets RD, and liquefaction of the refrigerant RF may be promoted. Then, since the liquefied refrigerant RF is efficiently dropped along the protrusions 76, a liquid film may be maintained thin at a portion where the protrusions 76 are not formed in the top plate 54. By maintaining the liquid film thin, a structure may be achieved in which movement of heat from the refrigerant RF in the gas phase to the top plate 54 is efficiently performed, and a high condensation and liquefaction capacity of the refrigerant RF is maintained.

The container 44 is provided with the fastening holes 88. By inserting the fasteners into the fastening holes 88, it is possible to easily achieve a structure in which the cooling device 42 is fixed to the substrate 34 and further fixed to the element 36 to be cooled.

The container 44 has the injection hole 92. Through the injection hole 92, the refrigerant RF may be easily injected into the inside of the container 44 through the injection pipe 96. Then, by filling the injection pipe 96 with the plug 94, a structure may be achieved in which the injection hole 92 is sealed with the plug 94, and the refrigerant RF is sealed inside the container 44.

In the technology of the present disclosure, the container 44, the evaporation unit 62, the condensation unit 72, the movement region 74, and the transport pipes 78 are not limited as long as they satisfy thermal conductivity, heat resistance, pressure resistance, and the like expected for the cooling device and may be made of metal. For example, when they are made of copper, they may exhibit high thermal conductivity. As a flow path member, a resin (silicone resin or the like) may be used other than metal.

By brazing, fusing, or adhering these members, for example, strength and airtightness of the container 44 may be secured high.

While the embodiments of the technology disclosed in the present application have been described thus far, the technology disclosed in the present application is not limited to the embodiments described above, and it will be understood that, Then to the embodiments described above, various modifications may be made and implemented within the spirit and scope of the technology.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A cooling device comprising:
a container in which a refrigerant is sealed;
an evaporation circuit that evaporates the refrigerant in a liquid phase inside the container by heat reception;
a condensation circuit that condenses the refrigerant in a gas phase inside the container by heat radiation;
a transport circuit that transports the refrigerant in the liquid phase inside the container to the evaporation circuit by a capillary phenomenon;
a heat radiation member that includes a plurality of fins attached to an outside of the container, and includes a narrow portion that has a width in a direction orthogonal to a flow direction of cooling air that is narrow on a downstream side in the flow direction, and a wide portion that has the width that is wide on an upstream side in the flow direction; and
an air guide member that is provided on the downstream side of the wide portion and on the upstream side of the narrow portion, and guides the cooling air that has passed through the wide portion to the narrow portion.

2. The cooling device according to claim 1, wherein the air guide member includes air guide plates that have a plate shape.

3. The cooling device according to claim 2, wherein the air guide plates are provided with through holes that penetrate the air guide plates in a plate thickness direction.

4. The cooling device according to claim 2, wherein the air guide plates are inclined to the narrow portion from the upstream side toward the downstream side.

5. The cooling device according to claim 4, wherein a plurality of the air guide plates is provided, and
the cooling device comprises an attachment plate that holds the plurality of the air guide plates and is attached to the wide portion and the narrow portion.

6. The cooling device according to claim 4, wherein the plurality of the air guide plates is arranged side by side in a width direction so that inclination angles relative to the flow direction become smaller toward an inside in the width direction.

7. The cooling device according to claim 2, wherein
the air guide plates include:
an outer plate portion that extends from the wide portion to the downstream side;
an inner plate portion that extends from the narrow portion to the upstream side; and
an intermediate plate portion continuous between the outer plate portion and the inner plate portion.

8. The cooling device according to claim 7, comprising an attachment plate that holds the outer plate portion, the inner plate portion, and the intermediate plate portion, and is attached to the wide portion and the narrow portion.

9. The cooling device according to claim 2, wherein the air guide member has a bilaterally symmetrical shape relative to a center line of the container along the flow direction.

10. The cooling device according to claim 1, wherein the container includes:
a heat reception circuit that receives heat from a target to be cooled and is provided with the evaporation circuit;
a heat radiation circuit that is separated from the heat reception circuit, releases the heat to the outside, and is wider than the heat reception circuit; and
a connection circuit that connects the heat reception circuit and the heat radiation circuit, and
the narrow portion is arranged in the heat reception circuit.

11. The cooling device according to claim 1, comprising
a gap portion that forms a gap between the transport circuit and the evaporation circuit, through which the refrigerant in the liquid phase moves from the transport circuit to the evaporation circuit.

12. The cooling device according to claim 1, wherein the transport circuit includes
transport pipes that transport the refrigerant in the liquid phase to the evaporation circuit by the capillary phenomenon.

13. The cooling device according to claim 12, wherein a plurality of the transport pipes is arranged in parallel.

14. The cooling device according to claim 12, which comprises a fixture that fixes the transport pipes to the container.

15. The cooling device according to claim 1, which comprises a column that is arranged between a top plate and a bottom plate of the container and maintains an interval between the top plate and the bottom plate.

16. The cooling device according to claim 1, wherein the condensation circuit includes a protrusion that protrudes from a top plate of the container to an inside of the container.

17. The cooling device according to claim 1, which comprises a fastening hole provided in the container, through which a fastener configured to fix the container to a target to be cooled is inserted.

18. A cooling device comprising:
a heat transfer member that receives heat of a target to be cooled;
a heat radiation member that includes a plurality of fins attached to an outside of the heat transfer member, and includes a narrow portion that has a width in a direction orthogonal to a flow direction of cooling air that is narrow on a downstream side in the flow direction, and a wide portion that has the width that is wide on an upstream side in the flow direction; and
an air guide member that is provided on the downstream side of the wide portion but on the upstream side of the narrow portion, and guides the cooling air that has passed through the wide portion to the narrow portion.
